(19) United States
(12) Patent Application Publication
(10) Pub. No.: US 2025/0313961 A1
(43) Pub. Date: Oct. 9, 2025

(54) CORROSION PROTECTION SYSTEM

(71) Applicant: Samuel Isaac Pattemore, Gray (AU)

(72) Inventor: Samuel Isaac Pattemore, Gray (AU)

(73) Assignee: Corrosion Instruments Pty Ltd, Yarrawonga (CA)

(21) Appl. No.: 19/244,621

(22) Filed: Jun. 20, 2025

Related U.S. Application Data
(63) Continuation-in-part of application No. PCT/AU2023/051366, filed on Dec. 22, 2023.

(30) Foreign Application Priority Data
Dec. 23, 2022 (AU) 2022904017

(51) Int. Cl. C23F 13/00; G01N 17/02

(52) U.S. Cl. CPC C23F 13/005; G01N 17/02

(57) ABSTRACT

A corrosion protection monitoring system having multiple test point monitors (2200) for monitoring the corrosion protection of a structure (5000) at synchronous timing of instant off or low power of corrosion protection units by coordination of internal clocks to an external clock (5100), (5200), wherein simultaneous interruption for say one second, allows simultaneous measurement at every single test point at an instant off or low electrical potential. Use of such multiple synchronous testing to provide cloud-based feedback control of optimising setpoints.

### CROSS-REFERENCE TO RELATED PATENT APPLICATIONS

This Patent Application is a Continuation-in-Part of co-pending Australian PCT Patent Application No. PCT/AU2023/051366, filed Dec. 22, 2023, which designated the United States and is now pending. This Patent Application and Australian PCT Patent Application No. PCT/AU2023/051366 claim priority to Australian Patent Application No. 2022904017, filed Dec. 23, 2022. The entire teachings and disclosure of each application are incorporated herein by reference thereto.

### FIELD OF THE INVENTION

The present invention relates to a corrosion protection monitoring and control system and in particular to a corrosion protection monitoring and control system for monitoring and controlling an Impressed Current Cathodic Protection (ICCP) arrangement and/or sacrificial cathodic protection arrangement or Galvanic Cathodic Protection (GCP) systems.

The invention has been developed primarily for use with impressed current cathodic protection and will be described hereinafter with reference to this application.

It also relates to Cathodic protection transformer rectifier units (also known as TR or TRU) which are used for Impressed Current Cathodic Protection (ICCP) systems. However, it will be appreciated that the invention is not limited to this particular field of use.

### BACKGROUND OF THE INVENTION

Corrosion of metals is a naturally occurring phenomenon caused by metals undergoing an electrochemical reaction when exposed to an electrically conductive environment (electrolyte) such as moist air, water, soil, or concrete.

An oxidation reduction (redox) reaction occurs between dissimilar sections within the metal substrate itself, caused by the surrounding conductive electrolyte enabling parts of the metal to chemically convert to its more chemically stable, less reactive form (typically as an oxide, in the case of Iron, Ferrous Oxide, i.e. rust).

Two dissimilar sections within the metals act as a galvanic cell (a battery) and allows a pathway through which free electrons move from the more active metal (the anode) to the less active metal (the cathode).

Corrosion reactions are accelerated by warmer temperatures and by increased concentrations of acids, salts or oxygen, as well as the nature or configuration of the structure being corroded.

Impressed Current Cathodic Protection (ICCP) works by polarising the protected structure with respect to its surrounding environment. It does this by applying a controlled direct current (DC) electrical voltage either through a power source (in the case of ICCP), or through electrical bonding to more active metals (in the case of Galvanic Cathodic Protection systems). This polarisation maintains the protected structure as the cathode with respect to the DC source's return path, preventing electrons from flowing from the protected structure and inhibiting the oxidation reduction (redox) reaction.

The impact of continuous corrosion may be factored into the design of substantial underground metal structures at inception, and the calculated expected end-of-life date is a significant factor when assessing the viability of any project involving investment in these substantial underground structures. Cathodic Protection is utilised to significantly slow the rate of corrosion. Generally, optimal cathodic protection is assumed when engineering the “corrosion allowance” which is the additional metallic wall thickness factored into the design to allow for corrosion.

Less-than-optimal Cathodic Protection results in greater corrosion rates than originally allowed for in the design. This can result in the structures failing prematurely, often accompanied by major safety implications and associated liabilities, as well as other financial losses due the unexpected interruption or termination of the service provided by the asset.

Any enhancement to the efficacy of providing Cathodic Protection (CP) across the life of these usually expensive underground structures that increases the likelihood of the structure maintaining its integrity up to and beyond its designed-in end-of-life, improves safety and the return on investment.

Impressed current cathodic protection typically utilises CP units that apply a DC current to the structure to be protected. Such CP units may be placed at regular spaced intervals along a structure such as a pipeline at distances of between hundreds of meters and hundreds of kilometers for example, between 300 m and 300 km. Test points or test point monitors may be provided for monitoring the polarization of the structure between CP units, as well as at CP units. These may be spaced regularly between the CP units at between around several meters and several kilometers apart, for example, between 5 m and 4 km apart.

Galvanic Cathodic Protection systems utilises Sacrificial Anodes that are highly active metals used to prevent a less active material surface from corroding. Sacrificial Anodes are selected from a metal alloy with a more negative electrochemical potential than the metal being protected. The Sacrificial Anode is corroded rather than the structure being protected.

Historically the effectiveness of CP has been impacted by inaccuracies in manual monitoring, resulting in subsequent errors when later calculating the optimum CP current to be applied to the structure under protection. These inaccuracies are often further compounded by the long delays that occur between the manual CP-Test-Point surveys of these structures as it can result in a fixed calculated current being applied across seasonally variable environments in which the structures lie.

To accurately determine the effectiveness of the CP, the structure's polarised potential relative to its surrounding environment must be measured. This is known as the structure's polarization. To accurately determine the effectiveness of the CP, the structure's potential relative to its surrounding environment must be measured. However, as polarisation is measured as a voltage, and as Voltage (“V”) is produced by Current (“I”) flowing through resistance (“R”), accurate polarisation measurement cannot be taken whilst the cathodic protecting current is flowing through the structure. This is because the Current (“I”) will flow from the structure, through the soil of resistance “R” offsetting the reading and resulting in what is known as an “IR error” or voltage error (V=I×R).

To ensure an error free polarisation measurement, the CP current is typically momentarily stopped. This is known as “current interruption”. The potential difference between the protected structure and its surrounding environment at the instant of current interruption, is the structure's polarisation due to the CP provided, and is known as the “instant off potential”.

A graph of the voltage between the structure being protected and its surrounding environment is shown in FIG. 1. Once the CP Current is interrupted, the potential between the structure and a reference electrode placed in the surrounding ground starts at its on potential and drops immediately by the magnitude of IR error to the instant off potential. From the instant off potential, the protected structure begins to depolarise immediately and will return to its native potential V_{Native} after some period if the CP current is not switched on again. Depolarisation is typically relatively fast initially, then decreases in rate over time. Therefore, potential must be measured after the IR error reduction in potential, but before depolarisation.

Either manual or automated measurement of the instant off potential may currently be carried out. An automated measurement of the potential (typically within about 100 ms+−5 ms of interrupting the CP current) will typically result in an accurate measurement of the instant off potential. Any delay in measurement after this will result in a depolarisation error V_{depol}. Manual measurement could occur up to about 500 ms after the interruption, although there is no certainty about the actual time of measurement, potentially resulting in a large depolarization error of unknown magnitude.

If the CP current is switched back on again (for example during cycling) then the IR is reapplied followed by a repolarization where the potential will return to the on potential.

For structures protected by more than one CP unit, if only one CP unit is switched off, the current from adjacent CP units may influence the readings measured at the test point monitors. For this reason, it is preferable to have all the CP units switched off synchronously with each other. CP units may be synchronised to switch off and on in a cyclic manner known as an interruption cycle (i.e. cycled), during which test point monitors may be configured to attempt to detect the cycling of the CP units, and take readings of the polarization of the structure without the IR error. However such detection of the cycling of power by the test point monitors is not always successful in practice, and typically requires relatively large amounts of energy to carry out.

Cathodic polarisation is typically lowest midway between two adjacent CP units and is greatest immediately adjacent a CP unit. It is desirable that monitoring of the potential is carried out at multiple points between two adjacent CP units. However, a power source may not be available at such a midpoint, and it may not be cost efficient to provide a power line along the entire length of a large structure such as a pipeline.

Rectifier or CP units are normally associated with a source of power. However, test point monitors rarely have a source of power that is readily available, unless they are located adjacent a CP unit. Further, structures being monitored, such as pipelines, may extend for vast distances through rough terrain and in locations that are far from reliable power sources or typical communication resources such as cellular communications towers.

A problem exists in systems that use pattern detection to synchronise with the interruption pattern. The procedure requires that the CP units be cycled through enough interruption periods for each test point monitor to confirm interruption and synchronise with the interruption pattern, and to subsequently take a measurement. Furthermore as the interruption pattern provides phase data but no absolute time data, the resulting measurements from multiple test point monitors are taken at unknown and different times.

The effectiveness and reliability of CP is impacted not only by these state-of-the-art limitations of not being able to readily deploy monitoring devices to existing, strategically placed CP monitoring points, but also by the nature of the ground soil itself. Unless moist, the impedance of soil is inherently high, thus measurements taken with low or even medium input impedance monitors will render readings with variable and generally insufficient accuracy.

Additionally, in situations where reference cells that are designed for permanent installation to enable continual monitoring of CP, are connected to the protected asset via a relatively low input impedance monitor, the cells can become polarised over time, rendering them ineffective as a reference in the long term. This then necessitates replacement of the reference cell, which is an expensive exercise, typically costing several times more than the cost of the test point monitor.

Any discussion of the background art throughout the specification should in no way be considered as an admission that such background art is prior art, nor that such background art is widely known or forms part of the common general knowledge in the field in Australia or any other country.

### SUMMARY OF THE INVENTION

The invention seeks to provide a corrosion protection monitoring system which will overcome or substantially ameliorate at least some of the deficiencies of the prior art, or to at least provide an alternative.

According to a first aspect, the present invention may comprise a corrosion protection test point monitor for monitoring the corrosion protection of a structure being protected, the corrosion protection monitoring system including:
a. an internal clock;
b. a processor operatively configured for executing digital instructions;
c. at least one or more transceivers configured for receiving and transmitting data;
d. a potential sensor for sensing the potential between the structure and the surrounding environment;
e. digital storage media operatively connected to the processor and configured for storing instructions configured for directing the processor to carry out the steps of:
   i. receiving a time signal from a geopositioning satellite;
   ii. synchronizing the internal clock according to the received time signal;
   iii. receiving a scheduling signal indicative of the scheduling of a survey event of at least one or more CP units located on the structure; and
   iv. measuring the potential between the structure and the surrounding environment at a predetermined time after the scheduled survey event.

In one embodiment, the survey event is a power off event.

In one embodiment, the instructions may be configured for directing the processor to carry out the step of transitioning to a low-power usage state between receiving the scheduling signal and a predetermined time before the scheduled survey event.

In one embodiment, the instructions may be configured for directing the processor to carry out the step of transitioning from a low power usage state to a higher power usage state at a predetermined time before the scheduled survey event.

In one embodiment, the instructions may be configured for directing the processor to carry out the step of transitioning from a low-power usage state to a higher power state at a predetermined time before the scheduled time for receiving the time signal from a geopositioning satellite.

In one embodiment, the instructions may be configured for directing the processor to carry out the step of transitioning from a high-power usage state to a low-power usage state after receiving the time signal from a geopositioning satellite.

In one embodiment, the instructions may be configured for directing the processor to carry out the step of transitioning from a high-power usage state to a low-power usage state after measuring the potential between the structure and the surrounding environment at a predetermined time after the scheduled survey event.

In one embodiment, the instructions may be configured for directing the processor to carry out the step of transmitting at least one or more measured potentials to a data management system.

In one embodiment, the instructions may be configured for directing the processor to carry out the step of transmitting the measured potential to a satellite.

In one embodiment, the instructions may be configured for directing the processor to carry out the step of transmitting the measured potential to a gateway device.

In one embodiment, the instructions may be configured for directing the processor to carry out the step of transitioning from a low-power usage state to a high-power usage state before transmitting the measured potential.

In one embodiment, the instructions may be configured for directing the processor to carry out the step of transitioning from a low-power usage state to a high-power usage state at a predetermined time before transmitting the measured potential.

In one embodiment, the instructions may be configured for directing the processor to carry out the step of transitioning from a high-power usage state to a to a low-power usage state after transmitting the measured potential.

In one embodiment, the instructions may be configured for directing the processor to carry out the step of storing the measured potential on the digital storage media.

In one embodiment, the instructions may be configured for directing the processor to carry out the step of receiving a synchronisation schedule for receiving a time signal from a geopositioning satellite.

In one embodiment, the instructions may be configured for directing the processor to carry out the step of storing the synchronisation schedule for receiving a time signal from a geopositioning satellite.

In one embodiment, the instructions may be configured for directing the processor to carry out the step of transitioning from a low-power usage state to a higher power usage state at a predetermined time before receiving the synchronisation schedule.

In one embodiment, the instructions may be configured for directing the processor to carry out the step of transitioning from a high-power usage state to a lower power usage state after receiving the synchronisation schedule.

In one embodiment, the instructions may be configured for directing the processor to carry out the step of storing the scheduling signal on the digital storage media.

In one embodiment, the internal clock is temperature compensated.

In one embodiment, the corrosion protection test point monitor includes a power storage device.

In one embodiment, the power storage device is a battery.

In one embodiment, the corrosion protection test point monitor includes a power generation device.

In one embodiment, the power generation device is one or more selected from:
a. a solar panel;
b. a wind turbine;
c. a device configured for harvesting power from current applied to a CP unit.

In one embodiment, the test point monitor has a high input impedance.

In one embodiment, the test point monitor has an input impedance of between 150 and 500 megaohms.

In one embodiment, the test point monitor has an input impedance of about 200 megaohms.

In one embodiment, the survey event is a stray current survey.

In one embodiment, the instructions may be configured for directing the processor to carry out the step of:
a. measuring the potential between the structure and the surrounding environment at a regular frequency; and
b. categorising the measured potentials between predetermined thresholds.

In one embodiment, the instructions may be configured for directing the processor to carry out the step of transmitting the number of measurements categorised within each threshold.

In one embodiment, the survey event is a depolarisation survey.

In one embodiment, the instructions may be configured for directing the processor to carry out the step of:
a. measuring the potential between the structure and the surrounding environment before a power off event as an on-potential;
b. measuring the potential between the structure and the surrounding environment after a power off event as an instant-off potential; and
c. monitoring the depolarisation of the structure relative to the surrounding environment over a survey period until a threshold criteria is met.

In one embodiment, the instructions may be configured for directing the processor to carry out the step of transmitting one or more selected from:
i. the measured on-potential;
ii. the measured instant off potential;
iii. the time required to reach the threshold criteria from the power off event;
iv. measurements at regular intervals over the survey period.

According to a further aspect, the present invention may comprise a method of monitoring the corrosion protection of a structure being protected, the method being carried out on a test point monitor located between two adjacent CP units of a corrosion protection system and comprising the steps of:
a. receiving a time signal from a geopositioning satellite;
b. synchronizing the internal clock according to the received time signal;
c. receiving a scheduling signal indicative of the scheduling of at least one survey event of at least one or more CP units located on the structure; and
d. measuring the potential between the structure and the surrounding environment at a predetermined time after the at least one scheduled survey event.

In one embodiment, the survey event is a power off event.

In one embodiment, the method includes the step of transitioning to a low-power usage state between receiving the scheduling signal and a predetermined time before the scheduled survey event.

In one embodiment, the method includes the step of transitioning from a low power usage state to a higher power usage state at a predetermined time before the scheduled survey event.

In one embodiment, the method includes the step of transitioning from a low-power usage state to a higher power state at a predetermined time before the scheduled time for receiving the time signal from a geopositioning satellite.

In one embodiment, the method includes the step of transitioning from a high-power usage state to a low-power usage state after receiving the time signal from a geopositioning satellite.

In one embodiment, the method includes the step of transitioning from a high-power usage state to a low-power usage state after measuring the potential between the structure and the surrounding environment at a predetermined time after the scheduled survey event.

In one embodiment, the method includes the step of transmitting the measured potential to a data management system.

In one embodiment, the method includes the step of transmitting the measured potential to a satellite.

In one embodiment, the method includes the step of transmitting the measured potential via a low power, wide area (LPWA) networking protocol.

In one embodiment, the method includes the step of transitioning from a low-power usage state to a high-power usage state before transmitting the measured potential.

In one embodiment, the method includes the step of transitioning from a low-power usage state to a high-power usage state at a predetermined time before transmitting the measured potential.

In one embodiment, the method includes the step of transitioning from a high-power usage state to a to a low-power usage state after transmitting the measured potential.

In one embodiment, the method includes the step of storing the measured potential on the digital storage media.

In one embodiment, the method includes the step of receiving a synchronisation schedule for receiving a time signal from a geopositioning satellite.

In one embodiment, the method includes the step of storing the synchronisation schedule for receiving a time signal from a geopositioning satellite.

In one embodiment, the method includes the step of transitioning from a low-power usage state to a higher power usage state at a predetermined time before receiving the synchronisation schedule.

In one embodiment, the method includes the step of transitioning from a high-power usage state to a lower power usage state after receiving the synchronisation schedule.

In one embodiment, the method includes the step of storing the scheduling signal on the digital storage media.

In one embodiment, the survey event is a stray current survey.

In one embodiment, the method includes the step of:
a. measuring the potential between the structure and the surrounding environment at a regular frequency; and
b. categorising the measured potentials between predetermined thresholds.

In one embodiment, the method includes the step of transmitting the number of measurements categorised within each threshold.

In one embodiment, the survey event is a depolarisation survey.

In one embodiment, the method includes the step of:
a. measuring the potential between the structure and the surrounding environment before a power off event as an on-potential measurement;
b. measuring the potential between the structure and the surrounding environment after a power off event as an instant-off potential measurement; and
c. monitoring the depolarisation of the structure relative to the surrounding environment over a survey period until a threshold criteria is met as a depolarization time measurement.

In one embodiment, the method includes the step of transmitting one or more selected from:
i. the on-potential measurement;
ii. the measured instant off potential measurement;
iii. the time required to reach the threshold criteria from the power off event;
iv. measurements of the polarization of the structure at regular intervals over the survey period.

According to a further aspect, the present invention may comprise a CP unit controller for controlling a CP unit for preventing the corrosion of a structure being protected, the CP unit controller including:
a. an internal clock;
b. a processor operatively configured for executing digital instructions;
c. at least one or more transceivers configured for receiving and transmitting data;
d. digital storage media operatively connected to the processor and configured for storing instructions configured for directing the processor to carry out the steps of:
   i. receiving a time signal from a geopositioning satellite;
   ii. synchronizing the internal clock according to the received time signal;
   iii. receiving a scheduling signal indicative of the scheduling of a survey event of at least one or more CP units located on the structure;
   iv. transmitting an interrupt signal to an interrupter in accordance with the scheduling signal, to thereby interrupt the electrical potential being created in the structure by the CP unit; and
   v. measuring the potential between the structure and the surrounding environment at a predetermined time after the scheduled survey event.

In one embodiment, the survey event is a power off event.

In one embodiment, the CP unit controller includes an interrupter configured for interrupting the electrical potential being created in the structure by the CP unit.

In one embodiment, the corrosion protection system includes a controller.

In one embodiment, the instructions may be configured for directing the processor to carry out the step of transmitting a measurement signal indicative of the measured potential between the structure and the surrounding environment.

In one embodiment, the instructions may be configured for directing the processor to carry out the step of transmitting a measurement signal indicative of a voltage output by a CP unit.

In one embodiment, the instructions may be configured for directing the processor to carry out the step of transmitting a measurement signal indicative of the voltage of the power supply which is available to an associated CP unit.

In one embodiment, the instructions may be configured for directing the processor to carry out the step of transmitting a setpoint to a CP unit.

In one embodiment, the instructions may be configured for directing the processor to carry out the step of receiving a feedback signal from a controller for correcting the potential to be applied to the structure.

In one embodiment, the instructions may be configured for directing the processor to carry out the step of adjusting the potential applied to the structure in accordance with the feedback signal.

In one embodiment, the survey event is a stray current survey.

In one embodiment, the instructions may be configured for directing the processor to carry out the step of:
a. measuring the potential between the structure and the surrounding environment at a regular frequency; and
b. categorising the measured potentials between predetermined thresholds.

In one embodiment, the instructions may be configured for directing the processor to carry out the step of the number of measurements categorised within each threshold In one embodiment, the survey event is a depolarisation survey.

In one embodiment, the instructions may be configured for directing the processor to carry out the step of:
a. measuring the potential between the structure and the surrounding environment before a power off event as an on-potential measurement;
b. measuring the potential between the structure and the surrounding environment after a power off event as an instant-off potential measurement; and
c. monitoring the depolarisation of the structure relative to the surrounding environment over a survey period until a threshold criteria is met as a depolarization time measurement.

In one embodiment, the instructions may be configured for directing the processor to carry out the step of transmitting one or more selected from:
i. the on-potential measurement;
ii. the measured instant off potential measurement;
iii. the time required to reach the threshold criteria from the power off event;
iv. measurements of the polarization of the structure at regular intervals over the survey period.

According to a further aspect, the present invention may comprise a corrosion protection system for preventing the corrosion of a structure being protected, the corrosion protection monitoring system including:
a. at least one or more CP units configured for connection to a power source and for creating an electrical potential in the structure, wherein the at least one or more CP units include:
   i. an internal clock;
   ii. a processor operatively configured for executing digital instructions;
   iii. an interrupter configured for interrupting the electrical potential being created in the structure;
   iv. at least one or more transceivers configured for receiving and transmitting data;
   v. digital storage media operatively connected to the processor and configured for storing instructions configured for directing the processor to carry out the steps of:
      1. receiving a time signal from a geopositioning satellite;
      2. synchronizing the internal clock according to the received time signal;
      3. receiving a scheduling signal indicative of the scheduling of a survey event of at least one or more CP units located on the structure; and
      4. interrupting the electrical potential between the structure and the surrounding environment in accordance with the scheduling signal.

In one embodiment, the survey event is a power off event.

In one embodiment, the corrosion protection system comprises at least one or more test point monitors as described above.

In one embodiment, the corrosion protection system comprises at least one or more CP unit controllers as described above.

In one embodiment, the corrosion protection system includes a controller.

In one embodiment, the instructions may be configured for directing the processor to carry out the step of transmitting a measurement signal indicative of the measured potential between the structure and the surrounding environment.

In one embodiment, the instructions may be configured for directing the processor to carry out the step of receiving a feedback signal from a controller for correcting the potential to be applied to the structure.

In one embodiment, the instructions may be configured for directing the processor to carry out the step of adjusting the potential applied to the structure in accordance with the feedback signal.

In one embodiment, the survey event is a stray current survey.

In one embodiment, the instructions may be configured for directing the processor to carry out the step of:
a. measuring the potential between the structure and the surrounding environment at a regular frequency; and
b. categorising the measured potentials between predetermined

In one embodiment, the instructions may be configured for directing the processor to carry out the step of the number of measurements categorised within each threshold. In one embodiment, the survey event is a depolarisation survey.

In one embodiment, the instructions may be configured for directing the processor to carry out the step of:
a. measuring the potential between the structure and the surrounding environment before a power off event as an on-potential measurement;
b. measuring the potential between the structure and the surrounding environment after a power off event as an instant-off potential measurement; and
c. monitoring the depolarisation of the structure relative to the surrounding environment over a survey period until a threshold criteria is met as a depolarization time measurement.

In one embodiment, the instructions may be configured for directing the processor to carry out the step of transmitting one or more selected from:
i. the on-potential measurement;
ii. the measured instant off potential measurement;
iii. the time required to reach the threshold criteria from the power off event;
iv. measurements of the polarization of the structure at regular intervals over the survey period.

According to a further aspect, the present invention may comprise a corrosion protection control system for preventing the corrosion of a structure being protected, the corrosion protection monitoring system including:
a. a processor operatively configured for executing digital instructions;
b. at least one or more transceivers configured for receiving and transmitting data;
c. digital storage media operatively connected to the processor and configured for storing instructions configured for directing the processor to carry out the steps of:
   i. receiving a measured potential signal indicative of the potential between the structure and the surrounding environment at a predetermined time after a scheduled survey event, the potential signal being received from one or more selected from
      1. a plurality of CP unit controllers;
      2. a plurality of CP units, and
      3. a plurality of test point monitors (the “measuring units”);
   ii. determining a feedback signal from the measured potential signals for transmission to each of the one or more selected from:
      1. plurality of CP unit controllers; and
      2. plurality of CP units; and
   iii. transmitting the feedback signal to each of the one or more selected from:
      1. a plurality of CP unit controllers; and
      2. a plurality of CP units (the “input units”).

In one embodiment, the corrosion protection system comprises an internal clock.

In one embodiment, the instructions may be configured for directing the processor to carry out the step of transmitting a scheduling signal indicative of the scheduling of a survey event of at least one or more CP units located on the structure to said one or more selected from:
i. a plurality of CP unit controllers;
ii. a plurality of CP units, and
iii. a plurality of test point monitors.

In one embodiment, the survey event is a power off event.

In one embodiment, the instructions may be configured for directing the processor to carry out the step of receiving one or more selected from the following ancillary date from the measuring units:
i. temperature;
ii. soil resistivity; and
iii. moisture levels.

In one embodiment, the instructions may be configured for directing the processor to carry out the step of determining the feedback signal utilising one or more selected from
i. the geopositioning of the test point monitors and/or CP units;
ii. geological structures proximate the locations of the monitors and/or CP units;
iii. current and/or past weather conditions at the locations of the test point monitors and/or CP units;
iv. atmospheric conditions at the locations of the test point monitors and/or CP units;
v. groundwater data at the locations of the test point monitors and/or CP units.

In one embodiment, the instructions may be configured for directing the processor to carry out the step of automatically determining a feedback signal from the measured potential signals for transmission to each of the input units.

In one embodiment, the instructions may be configured for directing the processor to carry out the step of assigning a weighted value to the potential measured at each of the measuring units based on one or more selected from:
i. their proximity to an input unit;
ii. the ambient temperature at the measuring unit;
iii. soil resistivity at the measuring unit;
iv. moisture levels at the measuring unit;
v. atmospheric conditions at the measuring unit; and
vi. the proximity of geological structures.

In one embodiment, the instructions may be configured for directing the processor to carry out the step of averaging the measured potential values of a predetermined number of measuring units to either side of an input unit.

In one embodiment, the instructions may be configured for directing the processor to carry out the step of dividing the measured potential of the measuring units by the desired potential to get a proportion.

In one embodiment, the instructions may be configured for directing the processor to carry out the step of averaging the proportions of a predetermined number of measuring units to either side of an input unit to obtain an averaged proportion for the associated input unit.

In one embodiment, the instructions may be configured for directing the processor to carry out the step of generating an adjusted setpoint for the associated input unit in accordance with the averaged proportion.

In one embodiment, the instructions may be configured for directing the processor to carry out the step of transmitting the adjusted setpoint to the associated input unit for adjustment of its setpoint as part of the feedback signal.

In one embodiment, the instructions may be configured for directing the processor to carry out the step of reducing the setpoint of an input unit if the measured polarisation exceeds a threshold value.

According to a further aspect, the present invention may comprise a method of controlling a corrosion protection control system for preventing the corrosion of a structure being protected, the method comprising the steps of:
a. receiving a measured potential signal indicative of the potential between the structure and the surrounding environment at a predetermined time after a scheduled survey event, the potential signal being received from one or more selected from
   i. a plurality of CP unit controllers;
   ii. a plurality of CP units, and
   iii. a plurality of test point monitors (the “measuring units”);
b. determining a feedback signal from the measured potential signals for transmission to each of the one or more selected from:
   i. plurality of CP unit controllers; and
   ii. plurality of CP units; and
c. transmitting the feedback signal to each of the one or more selected from:
   i. a plurality of CP unit controllers; and
   ii. a plurality of CP units (the “input units”).

In one embodiment, the method includes the step of transmitting a scheduling signal indicative of the scheduling of a survey event of at least one or more CP units located on the structure to said one or more selected from:
i. a plurality of CP unit controllers;
ii. a plurality of CP units, and
iii. a plurality of test point monitors.

In one embodiment, the method includes the step of:
a. determining the feedback signal utilising one or more selected from
   i. the geopositioning of the test point monitors and/or CP units;
   ii. geological structures proximate the locations of the monitors and/or CP units;
   iii. current and/or past weather conditions at the locations of the test point monitors and/or CP units;
   iv. atmospheric conditions at the locations of the test point monitors and/or CP units;
   v. groundwater data at the locations of the test point monitors and/or CP units.

In one embodiment, the instructions may be configured for directing the processor to carry out the step of automatically determining a feedback signal from the measured potential signals for transmission to each of the input units.

In one embodiment, the instructions may be configured for directing the processor to carry out the step of:
a. assigning a weighted value to the potential measured at each of the measuring units based on one or more selected from:
   i. their proximity to an input unit;
   ii. the ambient temperature at the measuring unit;
   iii. soil resistivity at the measuring unit;
   iv. moisture levels at the measuring unit;
   v. atmospheric conditions at the measuring unit; and
   vi. the proximity of geological structures.

In one embodiment, the method includes the step of averaging the measured potential values of a predetermined number of measuring units to either side of an input unit.

In one embodiment, the method includes the step of dividing the measured potential of the measuring units by the desired potential to get a proportion.

In one embodiment, the method includes the step of averaging the proportions of a predetermined number of measuring units to either side of an input unit to obtain an averaged proportion for the associated input unit.

In one embodiment, the method includes the step of generating an adjusted setpoint for the associated input unit in accordance with the averaged proportion.

In one embodiment, the method includes the step of transmitting the adjusted setpoint to the associated input unit for adjustment of its setpoint as part of the feedback signal.

In one embodiment, the method includes the step of reducing the setpoint of an input unit if the measured polarisation exceeds a threshold value.

A method of predicting the response of cathodic protection of a structure being protected by a cathodic protection system, the method comprising the steps of:
a. training a machine learning model on data of variables selected from one or more of:
   i. potential measurements of potential difference between a structure being protected by a cathodic protection system and its environment at the location of multiple monitors and/or CP units disposed on the structure;
   ii. the geopositioning of the test point monitors and/or CP units;
   iii. geological structures proximate the locations of the monitors and/or CP units;
   iv. current and/or past weather conditions at the locations of the monitors and/or CP units;
   v. groundwater data at the locations of the monitors and/or CP units;
b. generating a prediction model from the trained machine learning model;
c. predicting the effect of one or more of the variables on the cathodic protection of the structure.

In one embodiment, the method includes the step of transmitting a control correction signal to at least one CP unit based on the predicted effect of the variables.

It can be seen that the invention provides:
a. a system which can automatically interrupt all sources of cathodic protection current and simultaneously, with high timing precision, synchronously and thereby simultaneously measure instant off potentials at all test points.
b. The system can now undertake the instant off potential measurement or polarization measurement in a small time period (of the order of a second), so it can be completed often and used to measure instant off potentials frequently (nominally daily or hourly)
c. with frequent input of instant off measurements from all test points the system can implement closed loop control such that the current and/or voltage output at every source of cathodic protection can be optimised on an hourly or daily basis
d. the controlled sources of CP current can include sacrificial anodes
e. the cloud-based controller that can evaluate the data and computes and a series of setpoints for the CP units, which can be augmented with AI.
f. the synchronisation of all nodes with an external and ever-present time external source (GNSS) which allows coordination of all parts even without communication between parts. This can be undertaken extremely efficiently which enables permanently installed devices rather than devices that are installed for a surveying exercise and must be removed.

Other aspects of the invention are also disclosed.

The invention can be seen in one form to provide a cathodic protection management system fulfils a combination of one or more of the following functions:
1. Applies Continual Monitoring
2. Automates various types of cathodic protection surveys
3. Enables remote control of the application of cathodic protection
4. enables automatic, closed-loop control of the application of cathodic protection, based on the complete data set collected from the entire asset.
5. enables the use of AI to optimise this closed loop control of the application of CP on an Asset
6. enables the use of AI to optimise the application of CP on multiple assets that are collocated and such that their individual CP systems may affect the polarisation of each other.
7. enables the use of AI to produce outputs to control drainage bonds and traction drainage units to optimise CP and stray current across a complex network of co-located CP and Rail infrastructure.

Function 4 has the input to the control system being a plurality of sensors, enabling a holistic/asset-wide optimisation wherein the feedback signal is determined using a composite model incorporating all test point data across the asset to optimise corrosion protection uniformly and minimise localised under- or over-protection.

Function 5 has supervised learning or reinforcement learning which can use historical test point and environmental data to tune setpoints wherein the feedback signal is generated by an AI model trained on historic and real-time measurement data to optimise cathodic protection parameters.

Function 6 is concerned that adjacent assets can interfere (constructively or destructively), and optimisation must account for this wherein the AI model accounts for interference or interaction between the CP systems of adjacent or co-located assets in determining setpoints, thereby enabling coordinated CP optimisation across multiple assets.

Function 7 includes the controller outputs control signals to drainage bonds, traction drainage units or any other stray current mitigation devices based on analysis of measured potentials and predicted stray current interactions, enabling coordinated management of stray current and cathodic protection.

### BRIEF DESCRIPTION OF THE DRAWINGS

Notwithstanding any other forms which may fall within the scope of the present invention, a preferred embodiment of the invention will now be described, by way of example only, with reference to the accompanying drawings in which:

FIG. 1 shows a graph showing the potential between a structure and its environment when a CP unit is cycled off and then on again;

FIG. 2 shows a schematic diagram of a structure being protected, the structure being connected to CP units and test point monitors;

FIG. 3 shows a schematic diagram of a corrosion protection system on which the various embodiments described herein may be implemented in accordance with an embodiment of the present invention;

FIG. 4 shows a schematic diagram of a test point monitor;

FIG. 5 shows a schematic diagram of a CP unit;

FIG. 6 shows a schematic diagram showing the timing of the control of a series of test point monitors;

FIG. 7 shows a schematic diagram showing the timing of the control of a series of CP units;

FIGS. 8-10 shows a swim lane flow chart setting out the steps that may be carried out by a corrosion protection system;

FIG. 11 shows a flow chart setting out a method of predicting the response of cathodic protection of a structure being protected by a cathodic protection system;

FIG. 12 shows a schematic view of a CP unit controller

FIG. 13 shows a schematic of a closed loop control for updating CP unit setpoints of the predetermined thresholds; and

FIG. 14 shows a schematic of a cloud based closed loop control for updating CP unit setpoints of the predetermined thresholds and with use of AI.

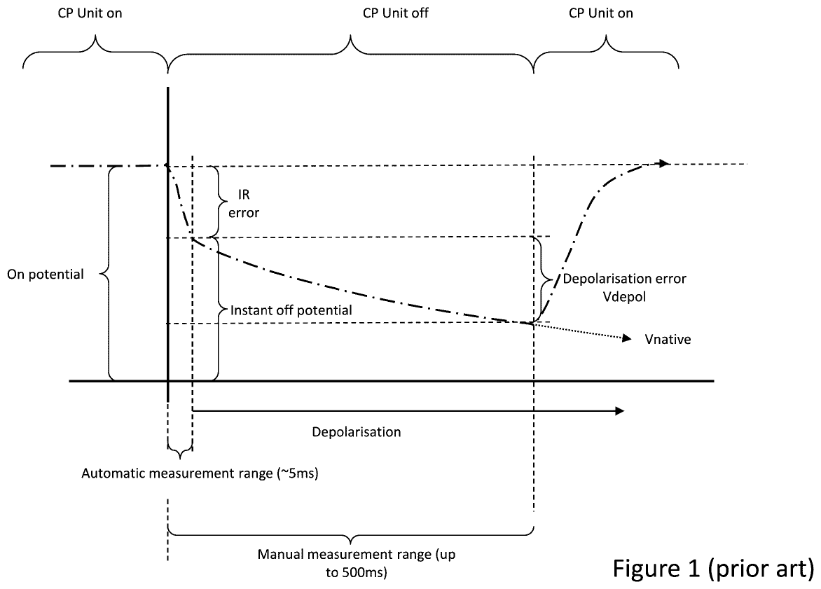

### DESCRIPTION OF EMBODIMENTS

It should be noted in the following description that like or the same reference numerals in different embodiments denote the same or similar features.

### Corrosion Protection System

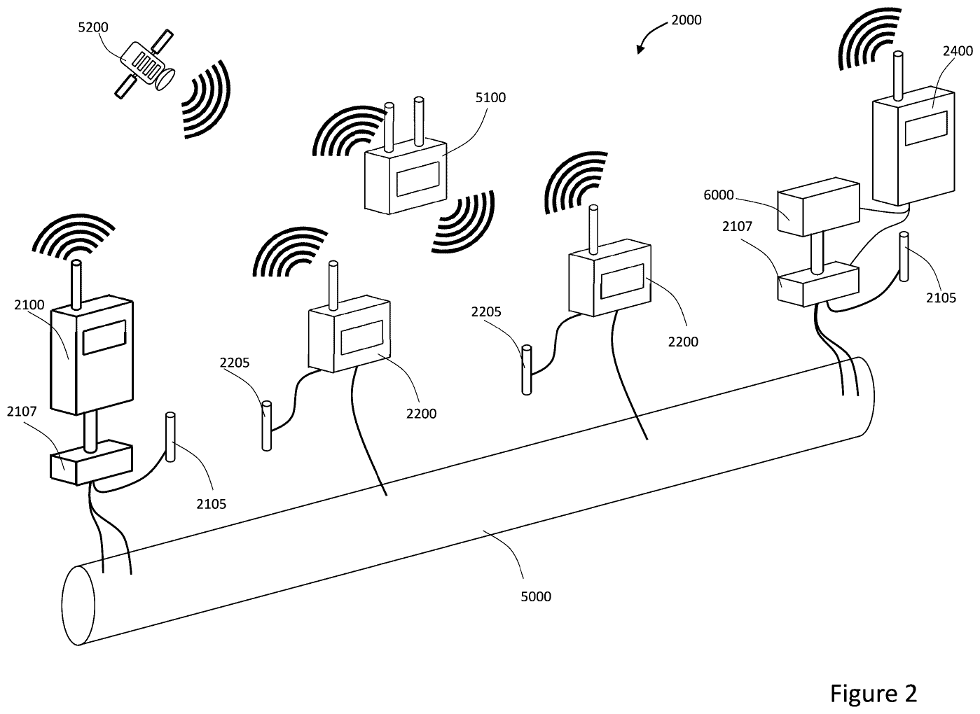

FIG. 2 shows a part of a corrosion protection system 2000. The corrosion protection system 2000 may include a plurality of transformer CP units or CP units 2100 that are spaced regularly along a structure 5000 to be protected by cathodic protection. The CP units 2100 are preferably powered by a reliable source of electrical power to create an electrical potential between the structure 5000 and the surrounding environment (i.e. a reference cell 2105 located in the ground). Such a source of electrical power may be from a connection to mains power, or from a connection to another source of electrical power.

Each of the CP units 2100 are provided with a current interrupter 2107, that are configured for interrupting the current being provided by the CP units 2100 to the structure 5000.

The corrosion protection system 2000 further includes structure-reference-instant-off-potential-sensors or test point monitors 2200 that are provided at regularly spaced intervals between the CP units 2100. The test point monitors 2200 are preferably located at positions where corrosion protection from the CP units is expected to be lowest and/or highest.

The test point monitors 2200 are configured for measuring the electrical potential between the structure 5000 and a reference cell 2205. To this end, the test point monitors 2200 preferably include a potential sensor 2210 for this purpose.

Preferably the test point monitors 2200 include a high internal impedance, preferably within the range of 150 megohms to 300 megohms or higher.

The test point monitors 2200 and the CP units 2100 are configured to act in synchronisation with each other as will be described in more detail below.

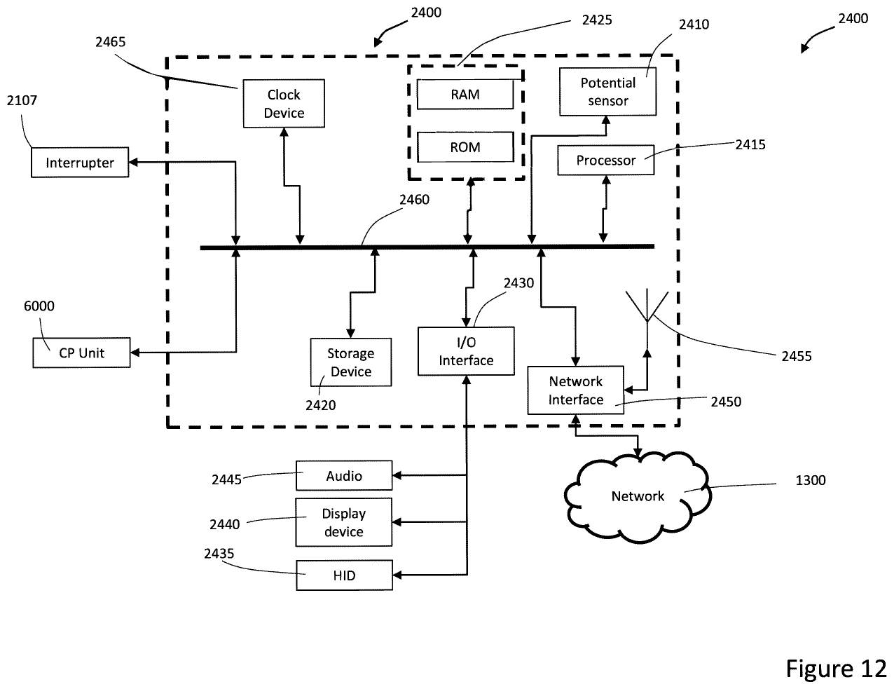

In addition to the above, it is envisaged that a CP unit controller 2400 (as shown in FIGS. 2 and 12) may be provided that can be retrofitted to existing “dumb” CP units 6000 (that for example only provides for a simple current or voltage control system, and possibly a current interrupter device) that will give them the functionality of the CP unit 2100 described above. Any reference to a CP unit 2100 below is envisaged as including a reference to a CP unit controller 2400 connected to an existing CP unit 6000 and interrupter.

The polarisation or potential difference of the structure 5000 relative to the environment created by the CP units 2100 is measured by the test point monitors 2200. The measured potential difference is sent by each of the test point monitors 2200 to a controller 2300, preferably over a wireless network. The wireless network or networks used may be any combination of a satellite communications network, a cellular communications network, a low power, wide area (LPWA) network using a protocol such as a LoRaWAN network, or any other suitable network.

For example, data may be sent from a CP unit 2100 or a test point monitor 2200 to a LoRaWAN Gateway device 5100, which may be placed at regular intervals along the structure 5000. The LoRaWAN gateway device may in turn transmit received data from the CP unit 2100 or test point monitor 2200 on to a communications satellite 5200 in a satellite communication network. Alternately, the CP unit 2100 and/or test point monitor 2200 may be configured for transmitting directly to communications satellite 5200, preferably disposed in a low-orbit position. It is envisaged that a wide variety of current and future networking protocols may be applicable. Some examples may include LoRaWAN to satellite or Narrowband Internet of Things (NBIoT).

The test point monitors 2200 as well as the CP units 2100 are configured for transmitting and receiving data over the wireless network. The test point monitors 2200 as well as the CP units 2100 are also preferably each configured for receiving a time signal directly from a geo-positioning satellite 5200.

In an alternative embodiment, the test point monitors 2200 as well as the CP units 2100 may be configured for receiving a time signal from a geo-positioning satellite 5200 via the LoRaWAN gateway device 5100.

It is envisaged that the test point monitors 2200 may be installed at locations that are inhospitable and rugged, and on which no reliable power source is available. For this reason, the test point monitors 2200 are each provided with a power storage device 2270 for storage of electrical power, such as a battery, super capacitor or other electrical power storage device.

In alternative embodiments (not shown), the test point monitors 2200 can further include some form of power generation device, such as a solar panel, wind turbine, or the like.

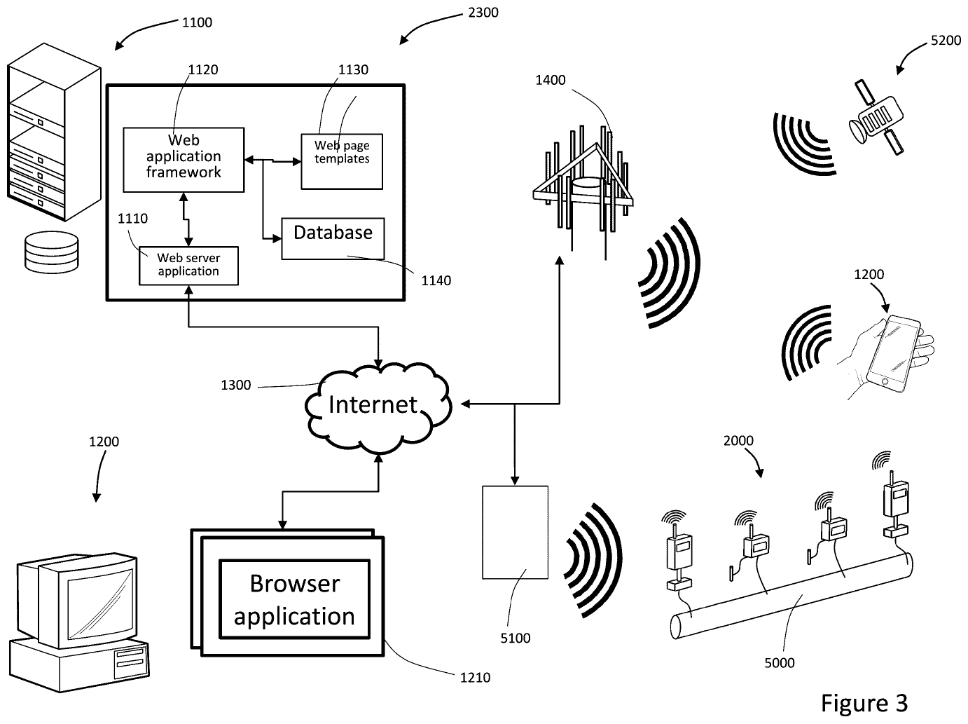

FIG. 3 shows a corrosion protection system 2000 in the form of a plurality of CP unit 2100 and test point monitors 2200 (as shown in FIG. 2) connected to a controller 2300. Data sent by the CP units 2100 and/or test point monitors 2200 are received by the controller 2300. The data may be received indirectly via third-party communication systems.

The controller 2300 is configured for analysing the received data from the CP units 2100 and/or test point monitors 2200, and generating a feedback signal which may be transmitted as feedback to the CP units 2100 and/or test point monitors 2200, with a view to ensuring that the polarisation of the structure 5000 is retained within a particular range. The polarisation range is preferably between −850 mV-2000 mV.

The controller 2300 preferably includes a computing device in the form of a cloud-based server 1100 (for example a server product offered by Amazon Web Services, Microsoft Azure, or Google Cloud) for storing analysis software, as well as for serving web pages to one or more client computing devices 1200 over the Internet 1300.

In a preferred embodiment, the server 1100 is a web server having a web server application 1110 for receiving requests, such as Hypertext Transfer Protocol Secure (HTTPS) and File Transfer Protocol Secure (FTPS) requests, and serving hypertext web pages or files in response. The web server application 1110 may be, for example the Apache™ or the Microsoft™ IIS HTTP server.

The server 1100 is also provided with a hypertext preprocessor or web application framework 1120 for processing one or more web page templates 1130 and data from one or more databases 1140 to generate hypertext web pages. The hypertext preprocessor may, for example, be the PHP: Hypertext Preprocessor (PHP) or Microsoft Asp™ hypertext preprocessor. The web server 1100 is also provided with web page templates 1130, such as one or more PHP or ASP files. In addition, mobile device based systems serving pages or information configured for display on mobile devices, whether as an app page or web page is envisaged.

Upon receiving a request from the web server application 1110, the web application framework 1120 is operable to retrieve a web page template from the web page templates 1130, execute any dynamic content therein, including updating or loading information from the one or more databases 1140, to compose a hypertext web page. The composed hypertext web page may comprise client-side code, such as Javascript, for Document Object Model (DOM) manipulating, asynchronous HTTP requests and the like. Additionally, client side code configured for generating a feedback signal may be hosted on the server 1100.

Client computing devices 1200 are preferably provided with a browser application 1210, such as the Google Chrome™, Mozilla Firefox™ or Microsoft Internet Explorer™ browser applications. The browser application 1210 requests hypertext web pages from the web server 1100 and renders the hypertext web pages on a display device for a user to view.

Client-side code is also downloadable as applications on the client computing device 1200 and/or server 1100, in order to facilitate the operation of and/or interaction with the corrosion protection system. Such applications could, for example, be downloaded from the Apple App Store™, Google Play™, or the like.

Client computing devices 1200 may communicate over the Internet 1300 or other networks such as satellite communication networks via fixed line or wireless communication, for example using known networks of cellular communication towers 1400 or communication satellites 5200.

In this way, client computing devices 1200 may access stored data on the server 1100 in order to manipulate and/or monitor the data.

It is envisaged that the controller 2300 will be configured to receive data from the test point monitors and CP unit monitors, and will be able to analyse the performance of the CP system as a whole instead of only at individual CP unit level.

In particular the controller 2300 will be configured to utilise the potential signal received from each of the test point monitors 2200 and CP units 2100, preferably with additional information about the environment surrounding these in order to generate a feedback signal for transmission to each of the CP units 2100 (i.e. including CP unit controllers 2400 installed on prior art dumb CP units 6000) in the form of a corrected control signal that will correct the potential being applied by each of the CP units 2100 in order to ensure that the structure is being adequately protected. Such additional information may include geopositioning of the monitors and/or CP units, geological structures at the locations of the monitors and/or CP units, weather conditions at the locations of the monitors and/or CP units, groundwater data at the locations of the monitors and/or CP units, and the like.

In addition, artificial intelligence, preferably in the form of machine learning may be provided on the server 1100 in order to monitor the data being received from the CP unit 2100 and/or test point monitors 2200, in order to more accurately predict voltages and/or currents to be applied by the CP units 2100 in order to retain the polarisation of the structure 5000 within a preferred range. In this way, control of individual CP units 2100 can be made more accurate in order to account for local effects such as ground moisture, ground composition, proximity to other structures, and the like. Further, the application of artificial intelligence will allow the system to learn how changing voltages and/or currents applied by one CP unit 2100 may affect the performance of the corrosion system as it relates to surrounding CP units 2100 and/or test point monitors 2200.

### Test Point Monitor

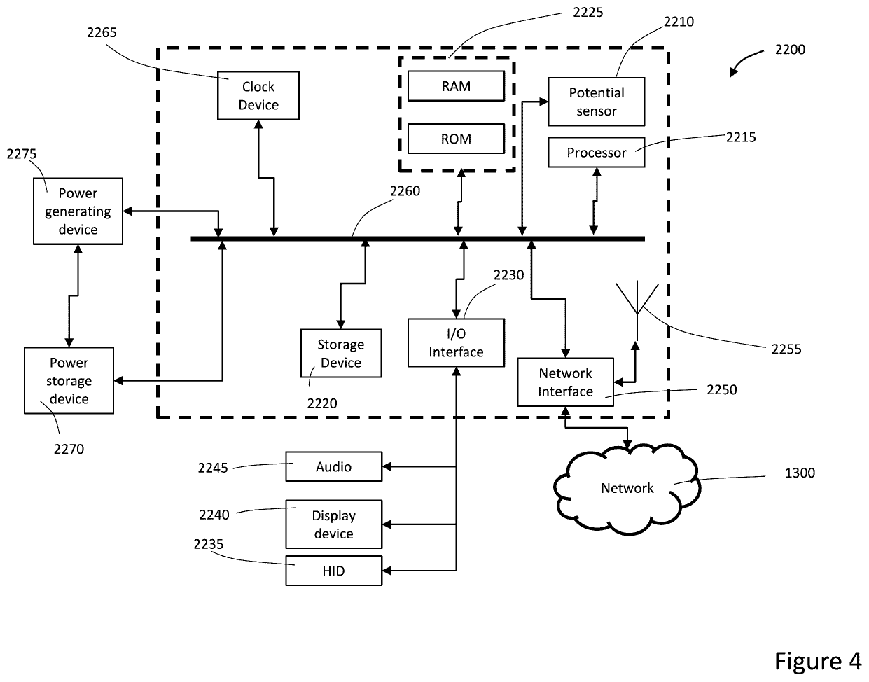

FIG. 4 shows a test point monitor 2200. In a preferred embodiment, the test point monitor 2200 is configured for standalone operation with its own power source. Preferably the test point monitor is also configured as a embedded system, and is a computing device in its own right, including a processor 2215, and digital storage media 2220 such as a solid-state drive or flash memory. Preferably the digital storage media will be power efficient in operation.

As mentioned previously, the test point monitor 2200 further includes a potential sensor 2210 configured for sensing the polarization or potential difference between the structure 5000 and a reference cell 2205.

The technical integers of the test point monitor 2200 as shown in FIG. 4 are exemplary only and variations, adaptations and the like may be made thereto within the purposive scope of the embodiments described herein and having regard for the particular application of the test point monitor 2200.

In particular the steps of the corrosion protection system, as described in further detail below, can be partially implemented as computer program code instructions executable by the test point monitor 2200.

The computer program code instructions may be divided into one or more computer program code instruction libraries, wherein each of the libraries performs one or more steps of the method. Additionally, a subset of the one or more of the libraries may perform graphical user interface tasks relating to the steps of the method.

The test point monitor 2200 preferably comprises semiconductor memory 2225 volatile memory such as random access memory (RAM) or read only memory (ROM).

The device further comprises I/O interface 2230 for communicating with one or more peripheral devices. The I/O interface 2230 may offer both serial and parallel interface connectivity. For example, the I/O interface 2230 may comprise a Small Computer System Interface (SCSI), Universal Serial Bus (USB) or similar I/O interface for interfacing with peripheral devices. The I/O interface 2230 may also communicate with one or more human input devices (HID) 2235 such as keyboards, pointing devices, joysticks and the like.

The I/O interface 2230 may also be configured as an audiovisual interface for interfacing the test point monitor 2200 with one or more display devices 2240, such as a liquid crystal display (LCD), light emitting diode (LED) display, organic light emitting diode (OLED) display, or similar display device. Alternately the test point monitor may include a built-in display device. The I/O interface 2230 may also comprise an audio interface 2245 for communicating audio signals to one or more audio devices (not shown), such as a speaker or a buzzer.

The test point monitor 2200 also comprises a network interface 2250 for communicating with one or more networks, such as the Internet 1300 and/or a satellite communications network. The network 1300 preferably utilises a low power, wide area (LPWA) networking protocol such as LoRa, or could be a satellite based network. The test point monitor 2200 can also include an antenna 2255 configured for wireless communication with network 1300.

The test point monitor 2200 comprises an arithmetic logic unit, microcontroller or processor 2215 for performing the computer program code instructions. The processor 2215 may be a reduced instruction set computer (RISC) or complex instruction set computer (CISC) processor or the like.

Computer program code instructions may be loaded into the storage device 2220 from the network 1300 using network interface 2250 or directly via the I/O interface 2230. Such computer program code instructions may be available from an online resource, and may be communicated wirelessly, for example using Bluetooth.

During the bootstrap phase, an operating system and one or more software applications are loaded from the storage device 2220 into the memory 2225. During the fetch-decode-execute cycle, the processor 2215 fetches computer program code instructions from memory 2225, decodes the instructions into machine code, executes the instructions and stores one or more intermediate results in memory 2225.

In this manner, the instructions stored in the memory 2225, when retrieved and executed by the processor 2215, configures the test point monitor 2200 as a special-purpose machine that may perform the functions described herein.

The test point monitor 2200 preferably includes a communication bus subsystem 2260 for interconnecting the various devices described above. The bus subsystem 2260 may offer connectivity using protocols such as I2C, Universal Asynchronous Receiver/Transmitter (UART), Serial Peripheral Interface (SPI) and the like.

Alternately the devices described above may be embedded in a System on a Chip (SoC). SoCs can be implemented as an application-specific integrated circuit (ASIC) or using a field-programmable gate array (FPGA) which typically can be reconfigured.

The test point monitor 2200 also includes a clock device 2265 configured for providing accurate time stamps for use by the processor 2215. The test point monitor 2200 will also include its own power storage device 2270, preferably in the form of a battery, although alternate power storage devices such as supercapacitors are also envisaged. The test point monitor 2200 also preferably includes a power generation device 2275, such as a solar panel, a wind turbine, or the like. The power generation device 2275 may be regulated by the test point monitor 2200.

### CP Unit

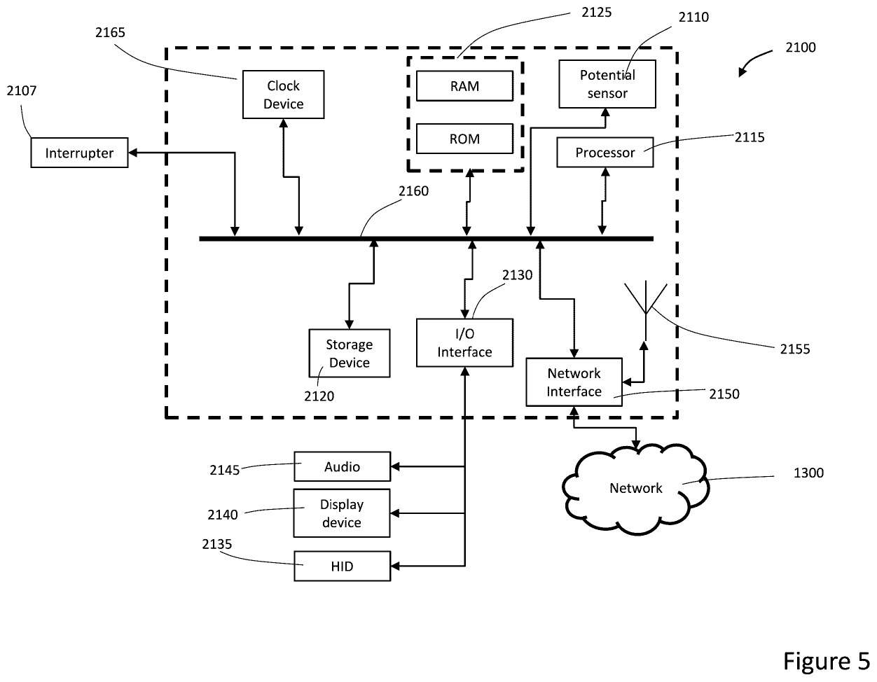

FIG. 5 shows a CP unit 2100. In a preferred embodiment, the CP unit 2100 is capable of carrying out much of the functionality of a monitor, and to this extent includes many of the components of the test point monitor 2200. However, the CP unit 2100 is also configured for applying a potential to a structure 5000, and for interrupting the applied potential, and includes suitable components for this, as will be described below.

In a preferred embodiment, the CP unit 2100 is configured for powered operation utilising power from a reliable power source, such as mains power. It is envisaged that the CP unit may be provided with some form of power generation device.

Preferably, the CP unit 2100 is also configured as a computing device in its own right, and includes a processor 2115, and digital storage media 2120 such as a solid state drive or flash memory. Preferably the digital storage media will be power efficient in operation.

As mentioned previously, the CP unit 2100 preferably includes much of the functionality of the test point monitor 2200 and includes a potential sensor 2110 configured for sensing the polarization or potential difference between the structure 5000 and a reference cell 2105.

The technical integers of the CP unit 2100 as shown in FIG. 5 are exemplary only and variations, adaptations and the like may be made thereto within the purposive scope of the embodiments described herein and having regard for the particular application of the CP unit 2100.

In particular the steps and methodology carried out by the corrosion protection system, as described in further detail below, can be partially implemented as computer program code instructions executable by the CP unit 2100.

The computer program code instructions may be divided into one or more computer program code instruction libraries, wherein each of the libraries performs a one or more steps of the method. Additionally, a subset of the one or more of the libraries may perform graphical user interface tasks relating to the steps of the method.

The CP unit 2100 preferably comprises semiconductor memory 2125 comprising volatile memory such as random access memory (RAM) or read only memory (ROM). The memory 2125 may comprise either RAM or ROM or a combination of RAM and ROM.

The device further comprises I/O interface 2130 for communicating with one or more peripheral devices. The I/O interface 2130 may offer both serial and parallel interface connectivity. For example, the I/O interface 2130 may comprise a Small Computer System Interface (SCSI), Universal Serial Bus (USB) or similar I/O interface for interfacing with peripheral devices. The I/O interface 2230 may also communicate with one or more human input devices (HID) 2135 such as keyboards, pointing devices, joysticks and the like.

The I/O interface 2130 may also be configured as an audiovisual interface for interfacing the CP unit 2100 with one or more display devices 2140, such as a liquid crystal display (LCD), light emitting diode (LED) display, organic light emitting diode (OLED) display, cathode-ray tube (CRT) or similar display device. Alternately the CP unit 2100 may include a built-in display device. The I/O interface 2130 may also comprise an audio interface 2145 for communicate audio signals to one or more audio devices (not shown), such as a speaker or a buzzer.

The CP unit 2100 also comprises a network interface 2150 for communicating with one or more networks, such as the Internet 1300 and/or a satellite communications network. The network 1300 preferably also utilises a low power, wide area (LPWA) networking protocol such as LoRaWAN or could be a satellite based network. The CP unit 2100 can also include an antenna 2155 configured for wireless communication with network 1300. The network interface could also be configured for communicating over a low power, local area network such as Bluetooth™, which could also be used to interface with local HID devices, displays, or computing devices such as mobile phones or tablets.

The CP unit 2100 comprises an arithmetic logic unit or processor 2115 for performing the computer program code instructions. The processor 2115 may be a reduced instruction set computer (RISC) or complex instruction set computer (CISC) processor or the like.

Computer program code instructions may be loaded into the storage device 2120 from the network 1300 using network interface 2250 or directly via the I/O interface 2130. Such computer program code instructions may be available from an online resource.

During the bootstrap phase, an operating system and one or more software applications are loaded from the storage device 2120 into the memory 2125. During the fetch-decode-execute cycle, the processor 2115 fetches computer program code instructions from memory 2125, decodes the instructions into machine code, executes the instructions and stores one or more intermediate results in memory 2125.

In this manner, the instructions stored in the memory 2125, when retrieved and executed by the processor 2115, configures the CP unit 2100 as a special-purpose machine that may perform the functions described herein.

The CP unit 2100 preferably includes a communication bus subsystem 2160 for interconnecting the various devices described above. The bus subsystem 2160 may offer connectivity using protocols such as I2C, Universal Asynchronous Receiver/Transmitter (UART), Serial Peripheral Interface (SPI) and the like. The CP unit 2100 also includes a clock device 2165 configured for providing accurate time stamps for use by the processor 2115.

### CP Unit Controller

Preferably the CP unit controller 2400 is also configured as a computing device in its own right, and includes a processor 2415, and digital storage media 2420 such as a solid-state drive or flash memory. Preferably the digital storage media will be power efficient in operation.

As mentioned previously, the CP unit controller 2400 further includes a potential sensor 2410 configured for sensing the polarization or potential difference between the structure 5000 and a reference cell 2105.

The technical integers of the CP unit controller 2400 as shown in FIG. 12 are exemplary only and variations, adaptations and the like may be made thereto within the purposive scope of the embodiments described herein and having regard for the particular application of the CP unit controller 2400.

In particular the steps of the corrosion protection system, as described in further detail below, can be partially implemented as computer program code instructions executable by the CP unit controller 2400.

The computer program code instructions may be divided into one or more computer program code instruction libraries, wherein each of the libraries performs a one or more steps of the method. Additionally, a subset of the one or more of the libraries may perform graphical user interface tasks relating to the steps of the method.

The CP unit controller 2400 preferably comprises semiconductor memory 2425 comprising volatile memory such as random access memory (RAM) or read only memory (ROM). The memory 2425 may comprise either RAM or ROM or a combination of RAM and ROM.

The device further comprises I/O interface 2430 for communicating with one or more peripheral devices. The I/O interface 2430 may offer both serial and parallel interface connectivity. For example, the I/O interface 2430 may comprise a Small Computer System Interface (SCSI), Universal Serial Bus (USB) or similar I/O interface for interfacing with peripheral devices. The I/O interface 2430 may also communicate with one or more human input devices (HID) 2435 such as keyboards, pointing devices, joysticks and the like.

The I/O interface 2430 may also be configured as an audiovisual interface for interfacing the CP unit controller 2400 with one or more display devices 2440, such as a liquid crystal display (LCD), light emitting diode (LED) display, organic light emitting diode (OLED) display, or similar display device. Alternately the test point monitor may include a built-in display device. The I/O interface 2430 may also comprise an audio interface 2445 for communicate audio signals to one or more audio devices (not shown), such as a speaker or a buzzer.

The CP unit controller 2400 also comprises a network interface 2450 for communicating with one or more networks, such as the Internet 1300 and/or a satellite communications network. The network 1300 preferably utilises a low power, wide area (LPWA) networking protocol such as LoRaWAN, or could be a satellite based network. The CP unit controller 2400 can also include an antenna 2455 configured for wireless communication with network 1300.

The CP unit controller 2400 comprises an arithmetic logic unit or processor 2415 for performing the computer program code instructions. The processor 2415 may be a reduced instruction set computer (RISC) or complex instruction set computer (CISC) processor or the like.

Computer program code instructions may be loaded into the storage device 2420 from the network 1300 using network interface 2450 or directly via the I/O interface 2430. Such computer program code instructions may be available from an online resource.

During the bootstrap phase, an operating system and one or more software applications are loaded from the storage device 2420 into the memory 2425. During the fetch-decode-execute cycle, the processor 2215 fetches computer program code instructions from memory 2425, decodes the instructions into machine code, executes the instructions and stores one or more intermediate results in memory 2425.

In this manner, the instructions stored in the memory 2425, when retrieved and executed by the processor 2415, configures the CP unit controller 2400 as a special-purpose machine that may perform the functions described herein.

The CP unit controller 2400 preferably includes a communication bus subsystem 2460 for interconnecting the various devices described above. The bus subsystem 2260 may offer connectivity using protocols such as I2C, Universal Asynchronous Receiver/Transmitter (UART), Serial Peripheral Interface (SPI) and the like.

Alternately the devices described above may be embedded in a System on a Chip (SoC). SoCs can be implemented as an application-specific integrated circuit (ASIC) or using a field-programmable gate array (FPGA) which typically can be reconfigured.

The CP unit controller 2400 also includes a clock device 2465 configured for providing accurate time stamps for use by the processor 2415. The CP unit controller 2400 will also include its own power storage device 2470, preferably in the form of a battery, although alternate power storage devices such as supercapacitors are also envisaged.

### Functionality

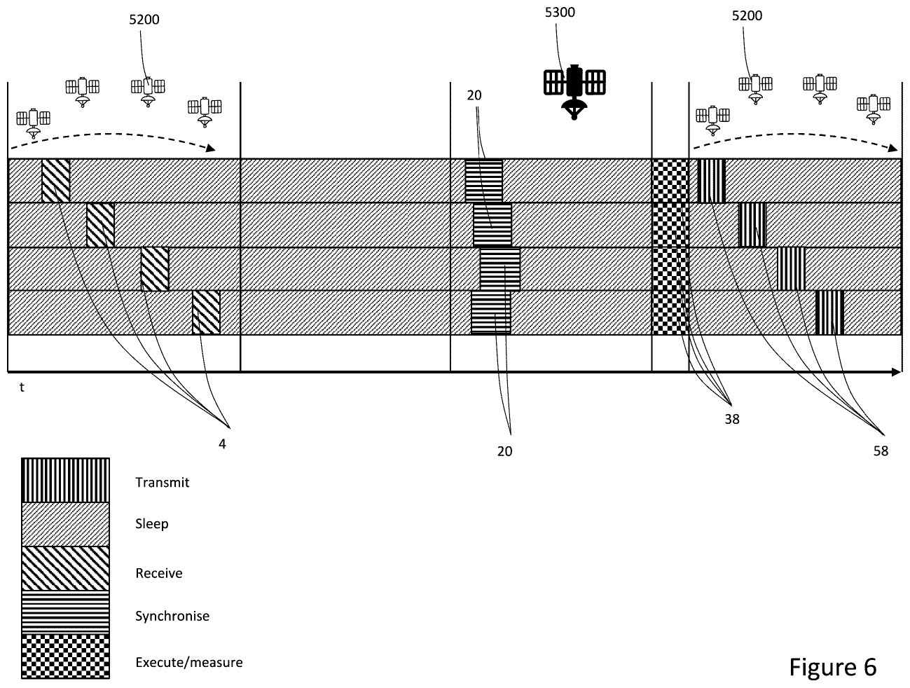

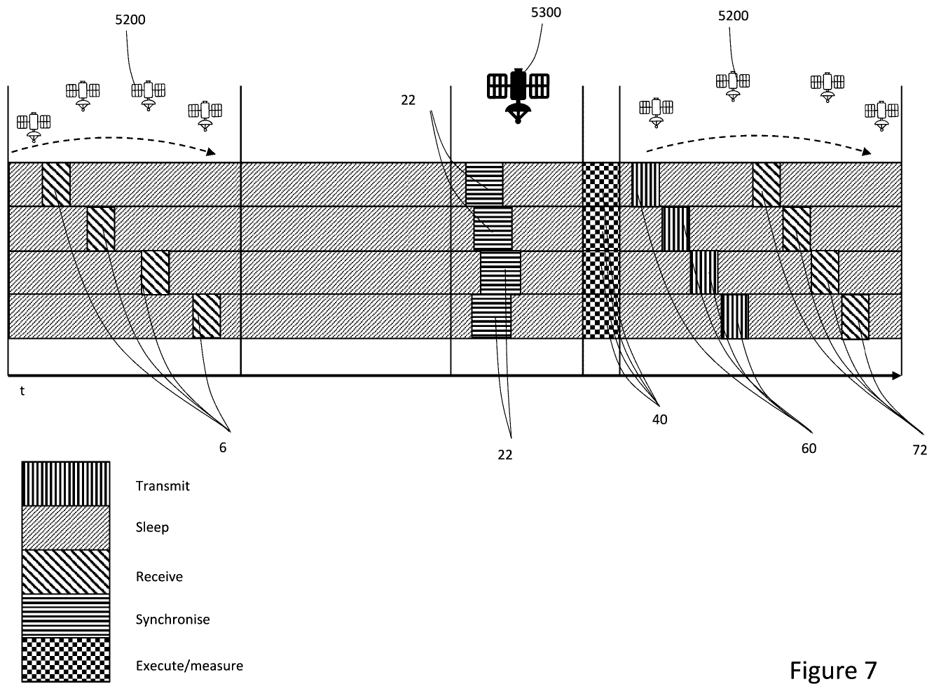

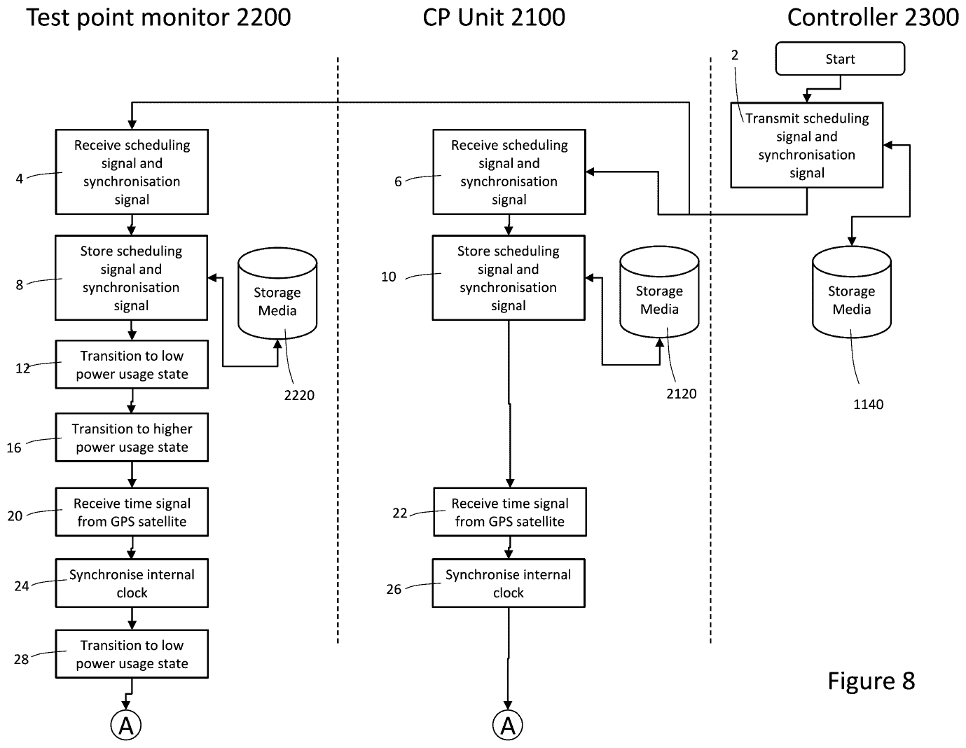

The functionality of the various embodiments described above will now be explained with reference to the flowcharts shown in FIGS. 8-10, and as illustrated in FIGS. 6 and 7. In a discussion of the methodologies below, communications are preferably over a secure communication network, and in encrypted format.

Now referring to FIG. 8, the controller 2300 will initially transmit 2 a scheduling signal to the CP unit 2100 and test point monitor 2200 over the network. The scheduling signal is indicative of the timing of a survey event when one or more potential measurements are to be executed, preferably provided as one or more times and dates. The survey event could be a power off event where the power to the CP units are turned off at exactly the same time, and the off potential is measured at a predetermined time after the power has been turned off. Alternatively the survey event could be of different types, such as when alternative tests or surveys are carried out by the test point monitors 2200 and/or CP unit controllers.

For example, the survey event may be a stray current survey. In a stray current survey, the test point monitors 2200, CP Units 2100 and/or CP unit controllers 2400 are configured to carry out the step of measuring the potential between the structure and the surrounding environment (or reference cell 2105, 2205). Each of the measured potentials of the stray current survey may in turn be transmitted to the controller 2300. In another example each measured potential may be categorised within predetermined thresholds, and the number of measurements within each threshold may then be transmitted to the controller 2300.

In another example, the survey event may be a depolarisation survey. In a depolarization survey, the test point monitors 2200, CP Units 2100 and/or CP unit controllers 2400 are configured for measuring the potential between the structure and the surrounding environment before a power off event as an on-potential; then measuring the potential between the structure and the surrounding environment immediately after a power off event as an instant-off potential; as well as monitoring the depolarisation of the structure relative to the surrounding environment at regular intervals over a survey period until a threshold criteria is met. The results of the depolarization survey that may be transmitted to the controller 2300 include the measured on-potential; the measured instant off potential; the time required to reach the threshold criteria from the power off event; and/or measurements at regular intervals over the survey period.

The scheduling signal may also include details of when such measurements are to be transmitted to the controller 2300 via the network and/or when information is to be received from the controller 2300 via the network. The scheduling signal is indicative of a suitable synchronisation time for the respective devices (either the test point monitor, the CP unit controller or the CP unit, or both) to synchronise their internal clock devices 2165, 2265 with the time received from a geo-positioning satellite. The scheduling signal may further provide details of which geo-positioning satellite to use. For example, the scheduling signal may provide scheduling information for performing an instant off measurement once per day. In another application, for example the scheduling signal may provide scheduling information for commencing a depolarisation survey or a stray current survey. Stray current surveys may, for example, be scheduled once annually while instant off measurements may be conducted once daily.

The CP unit 2100 and the test point monitor 2200, and be configured for receiving 4, 6 the scheduling signal. On receiving 4, 6 the scheduling signal, these will be stored 8, 10 on the digital storage media 2120, 2220 of the CP unit and monitor, respectively. The test point monitor 2200 will then transition 12 to a low-power usage state (or “sleep” state) in which power is only used for keeping track of the time and date on their internal clock devices 2265.

At a predetermined time before the synchronisation time, the test point monitor will “wake” or transition 16 to a higher power usage state in which communications from the geo-positioning satellite may be monitored. The CP unit 2100 and test point monitor 2200 will then receive 20, 22 the time signal from the geo-positioning satellite.

It should be noted that the CP unit 2100 and test point monitor 2200 may be configured for receiving 20, 22 the time signal directly from the geo-positioning satellite, or alternatively the time signal may be received directly from the geo-positioning satellite or indirectly from a LoRaWAN gateway device 5100 which is configured to receive the time signal directly from the geo-positioning satellite or by means of another network time protocol.

After receiving 20, 22 the time signal, the test point monitor and the CP unit will synchronise 24, 26 their internal clocks 2165, 2265 to the time signal received from the geo-positioning satellite.

The test point monitor will then transition 28 to a low power usage or “sleep” state. During this low-power usage state, it is anticipated that the clock devices 2165, 2265 of the test point monitor 2200 and the CP unit 2100 will remain synchronised. The clock devices are preferably also temperature compensated in order to reduce the likelihood of large differences in the time readings between the test point monitor and the CP unit.

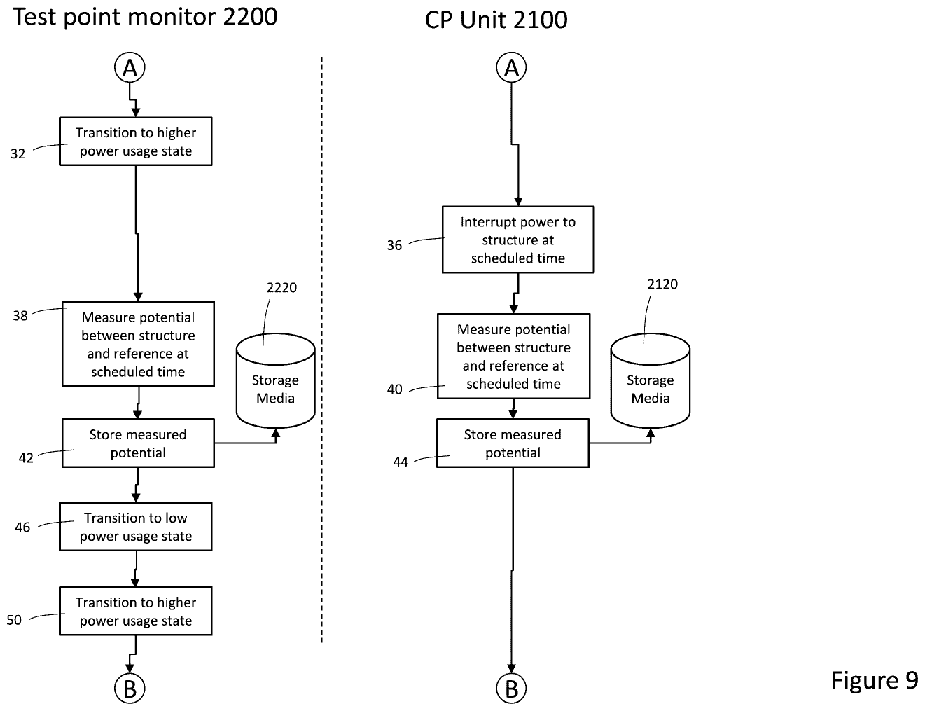

Now following on from reference numeral A on FIG. 8, and referring to the same reference numeral A on FIG. 9, at a predetermined time before the scheduled measurement time for measurement of the polarisation of the structure, the test point monitor will transition 32 to a higher power usage state. It is anticipated that this transitioning 32 to a higher power usage state will occur at a very short time before the scheduled measurement time in order to avoid wasting power.

At the precisely synchronised scheduled measurement time, the current interrupter 2107 of the CP unit 2100 will cause the current that is being applied by the CP units 2100 along the structure 5000 to be interrupted.

At a predetermined time-preferably around 5 ms to 15 ms after the current is interrupted-the CP unit 2100 and the test point monitor 2200 will measure 38, 40 the polarisation of the structure 5000 relative to reference cells 2105, 2205.

It is anticipated that, because the CP units 2100 and test point monitors 2200 have all been synchronised to the exact same time, the current will be interrupted 36 in the CP units 2100 at precisely the same time, and the test point monitors 2200 and CP units 2100 will take the potential measurements at precisely the same time after the interruption, and preferably after an optimal or close to optimal time delay after the interruption.

After the polarisation of the structure has been measured 38, 40 by both the CP units and monitors, the measurements will be stored 42, 44 on the digital storage media 2120, 2220 of the CP unit 2100 and test point monitor 2200 respectively. The test point monitor will then transition 46 to a low power usage state again in order to reduce power usage.

It is anticipated by the applicant that the transition to a low-power usage state for most of the time period that the test point monitor is in use, will allow the test point monitor to be exceptionally frugal on power usage, and allow for an extended time period of usage of the test point monitor of up to, or in excess of, 10 years without having to replace or recharge the batteries.

The requirement for the CP unit 2100 to be frugal on power usage is not as pressing as the CP unit 2100 may be provided a reliable source of electricity. However, it is important that the CP unit and the test point monitor be precisely synchronised for the time period where current is interrupted in the structure, and for the short time period thereafter in which the polarisation of the structure is measured by the test point monitors 2200.

At a predetermined time immediately preceding the scheduled communication time, the test point monitor will transition 50 to a higher power usage state in order to prepare to communicate the measured potentials to the controller 2300.

The scheduled communication time is not required to be as precise as the measurement times. However, because the internal clocks 2165, 2265 are already closely synchronised to the real time, the communication times should automatically be very close to the real time.

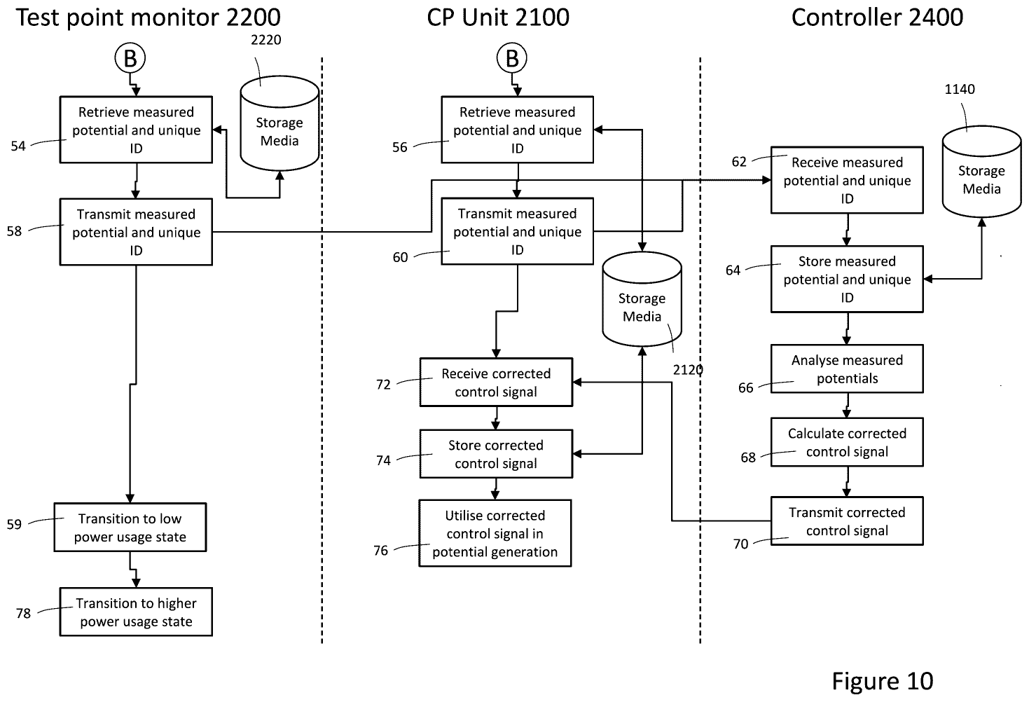

As shown in FIG. 10, transitioning from reference numeral B in FIG. 9, once the test point monitor 2200 and CP unit 2100 of transitioned 50, 52 to a higher power usage state, they will retrieve 54, 56 the measured potential from the storage media 2220, 2120, preferably with a unique identifier associated with each of the monitors and/or CP units. The potential measurements and unique identifier will then be transmitted 58, 62 the controller, preferably via the communications satellite 5200 and/or the LoRaWAN Gateway device 5100 as a potential signal. The test point monitor 2200 will then preferably transition 59 to a low-power usage state immediately after transmitting 58 the measured potential and unique identifier.

On receiving 62 the potential signal including the measured potential and unique identifier of each of the test point monitors 2200 and CP units 2100, the controller 5300 will store 64 the measured potential together with the unique identifier on the database 1140. Analysis software on the controller will then analyse the measured potentials in order to establish whether they are within the required thresholds for cathodic protection to be effective. If the measured potentials are not within the required thresholds, the controller 5300 will calculate 68 a corrected control signal for the CP units 2100. The corrected control signal will then be transmitted 70 to the relevant CP units.

On receiving 72 the corrected control signal, the CP unit 2100 will store 74 the corrected control signal, and begin utilising 76 the corrected control signal in generating the potential between the structure 5000 and the reference cell 2105.

The test point monitor 2200 will in turn transition to a higher power usage state at a predetermined time before the next scheduling signal and synchronisation signal is due to be sent to the monitor.

It is further envisaged that since a large structure 5000 being protected, such as a pipeline, can include many CP units and can extend over a long distance, the scheduled times for each CP unit and/or test point monitor to communicate the measured potentials to the controller may be staggered. This is illustrated in FIGS. 6 and 7, where the monitors and CP units are woken up in sequence as a communications satellite passes above them over the length of the structure. FIG. 7 shows both a transmission time where the CP unit transmits the potential measurement to the controller, as well as a reception time where at the CP unit receives a corrected control signal from the controller 2300. It should be noted that the provision of separate transmission/reception times is not a requirement, and that transmission and reception can be carried out at a single time. However, it is envisaged that the controller 2300 would preferably receive all of the potential measurements from all of the CP units and monitors before analysing these and providing corrected control signals to the CP units.

In a preferred embodiment, it is envisaged that separate controller processor units may be provided—one for communication and one for control/measurement/logic. The communication processor can be woken up when there is a satellite overhead and data is required to be transmitted or received, or where the logic processor needs to past data to the communications controller. It is envisaged that the logic processor will remain in a low power usage state except when it is required to take a measurement, pass data to the communications processor, or synchronise the internal clock. This allows the logic processor to remain in a low power state for more than 99.95% of the time.

In this way, it is envisaged that regular patterns of cathodic protection interruption and simultaneous reading of measurements will be enabled while also allowing for battery-powered monitoring to be provided over rugged and isolated terrain where reliable electrical power is not available, and where common communication methods such as cellular communications are not available.

Further, the provision of a LoRaWAN gateway device also allows for measurement of structures by monitors that are hidden under other structures, and which may not be able to transmit directly to a communications satellite.

It is further envisaged that the provision of regular readings from the monitors and CP units will allow for corrected control signals to be provided to the CP units and/or CP unit controllers at frequent intervals, thereby reducing the effect of any anomaly which may increase the amount of corrosion on a structure. Further, the large amount of data received by the controller at frequent intervals (preferably daily) allows for the use of machine learning on the received data, with a view to providing correction signals generated by a machine learning module trained on the data received by the controller. Such data relating to potential measurements may also be combined with additional data such as the geopositioning of the monitors and/or CP units, geological structures at the locations of the monitors and/or CP units, weather conditions at the locations of the monitors and/or CP units, groundwater data at the locations of the monitors and/or CP units, and the like.

It is envisaged that, on receiving a set of potential signals from each of the plurality of CP unit controllers; plurality of CP units, and plurality of test point monitors (the “measuring units”), the controller 2300 will then preferably automatically determine a feedback signal from the measured potential signals. The determination of the feedback signal may be by application of a particular algorithm.

The feedback signal will be transmitted to the plurality of CP unit controllers and all plurality of CP units (the “input units”). The feedback signal will preferably allow for adjustment of a setpoint on the input units. The input units will then be controlled to meet the new adjusted setpoint.

It is further envisaged that, together with the measured potential, the test point monitors may measure and transmit data indicative of the local surroundings, including temperature measurements, soil resistivity measurements, and/or moisture levels in the air and/or ground.

The algorithm by which the feedback signal may be automatically determined may assign a weighted value to the potential measured at each of the measuring units based on one or more selected from their proximity to an input unit; the ambient temperature at the measuring unit; soil resistivity at the measuring unit; moisture levels at the measuring unit; atmospheric conditions at the measuring unit; and/or the proximity of geological structures or other variables.

For example, if high soil resistivity is known to increase the potential between the structure 5000 and the surrounding soil, then the controller 2300 may determine that high soil resistivity in a particular area would require that the charge being applied by an input unit in that area would need to be reduced. Similar considerations would be used to determine the effect of factors such as ambient temperature and moisture levels.

It is further envisaged that the controller 2300 may divide the received measured potential values of the measuring units by the desired potential values to obtain a proportion number. The controller 2300 may then average the proportion numbers of a predetermined number of measuring units to either side of an associated input unit to get a setpoint factor. The controller 2300 may then use the setpoint factor to adjust the present setpoint for the associated input unit, for example by multiplying the present setpoint by the setpoint factor to obtain an adjusted setpoint. The adjusted setpoint will then be transmitted to the associated input unit for adjustment of that setpoint as part of the feedback signal.

It is then envisaged that the localised controllers of the CP units 2100 and/or CP unit controllers 2400 will control output in accordance with the adjusted setpoint.

In determining new setpoint values to be sent to the input units, the controller 2300 will be preferably attempting to keep the potential between the structure 5000 and the surrounding ground between −850 mV and −2000 mV, although this may vary.

Further, if the potential values received in the potential signals are already beyond a particular threshold (say below −2000 mV), and over protection is occurring, the controller 2300 will reduce the setpoint value by the proportion between the measured potential and the desired potential.

In an alternative embodiment, it is envisaged that, certain input units may be associated with measuring units. On receiving the potential signals from the measuring units, the controller 2300 may determine that a certain number of measured potential values are not within a desired range. The controller may apply a predetermined step increase to the present setpoint for input units associated with the measuring units to generate an adjusted setpoint. The adjusted setpoint will then be transmitted to the input units, where the adjusted setpoint will be used by the localised control systems of the input units to control the charge being applied.

It is further envisaged that the controller 2400 could implement a wide variety of control schemes including proportional (P), proportional integral (PI), proportional derivative (PD), proportional integral derivative (PID), cascade, or any type transfer function, or any combination of these. In addition, various control system controls could be applied including limits, ramp rates, learning functions, and the like.

It is further envisaged that various ancillary variables could be included into the control scheme to increase performance. Control variables may also be manually adjustable by a user, or by a machine learning system as will be described in more detail below.

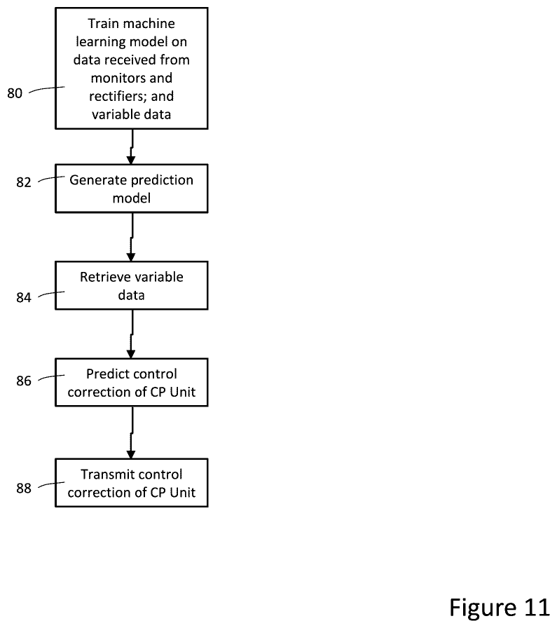

Referring now to FIG. 11, it is envisaged that a machine learning model such as a neural network may be trained 80 on such data, and a prediction model generated 82 from the trained neural network/machine learning.

It is further envisaged that, after retrieving 84 past, current or forecast variable data, such a prediction model can be then used to predict 86 the effect of the above variables on cathodic protection of the structure being provided by the CP units, and anticipate required changes to current and/or voltage applied by the CP unit to the structure in order to provide effective cathodic protection. In this way, corrosion of the structure may be further reduced whilst also increasing the power efficiency of the CP units. The anticipated required changes can be generated as a control correction signal and transmitted 88 to the CP unit for implementation by the CP unit in anticipation of the potential effects of the variables.

While the above has been described with reference to impressed current cathodic protection, it is envisaged that the same approach can be adopted for Galvanic Cathodic Protection systems which employ sacrificial anodes. The system may utilize analogue control of the sacrificial anodes to control the cathodic current they each apply this would be done through the use of a varistor type circuit. Alternatively, the system may utilise digital techniques or high-speed switching such as thyristors to control the cathodic current which is applied by the sacrificial anode over time. This is separate to and in addition to the precision Binary switching of the sacrificial anode achieved through the relay that is required to perform certain surveys. Analogue control may enable the ability to control the current which is applied from a sacrificial anode based on the measurements and survey data collected using the processes described.

For example, the system may be used to remotely adjust the current and amount of protection being provided by the sacrificial anode. Further, the cloud based closed loop control system may be implemented to automatically adjust the amount of protection being provided by each sacrificial anode. The machine learning models described above may also be configured to control the sacrificial anodes (both independently or in combination with the CP units) to optimise control of overall protection of the structure.

### Closed Loop

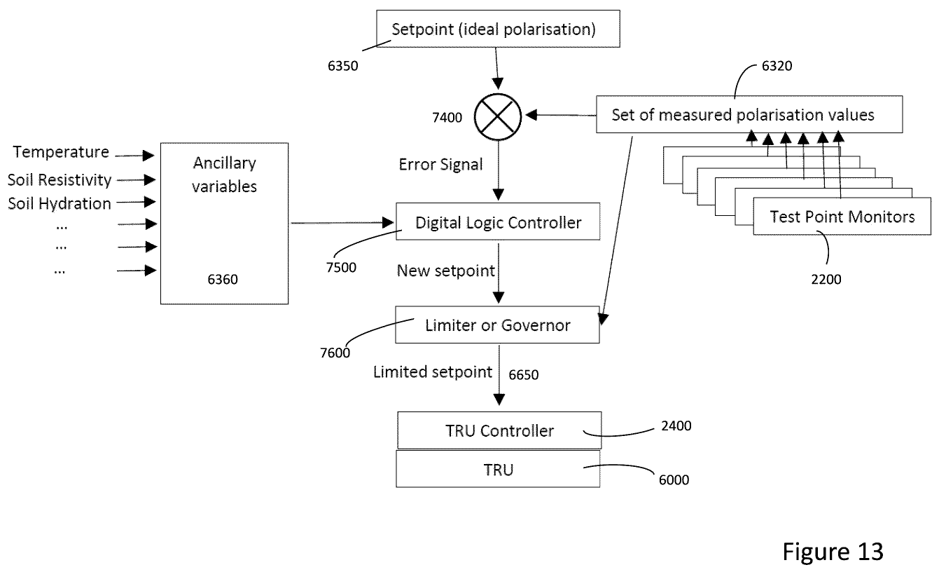

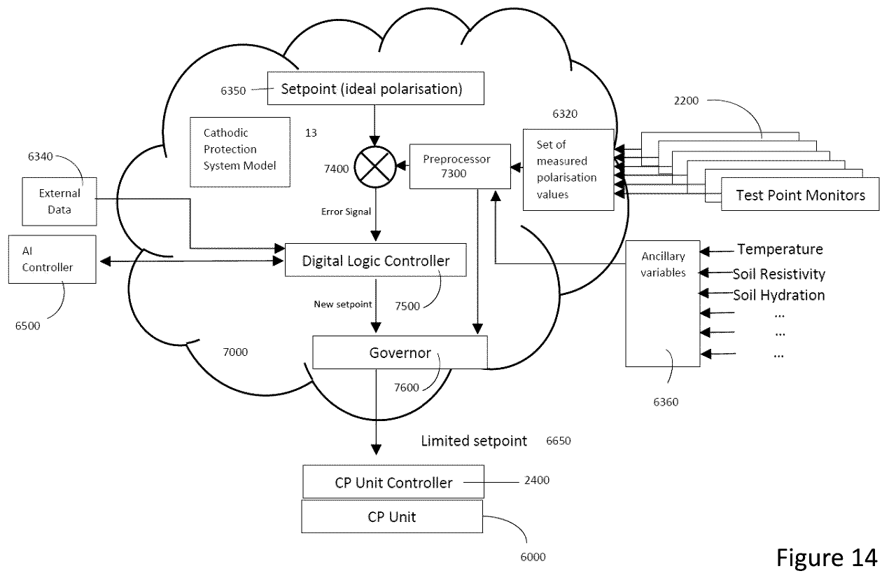

Referring to FIGS. 13 and 14 there is shown in FIG. 13 a schematic of a closed loop control for updating CP unit setpoints of the predetermined thresholds. In FIG. 14 there is shown a schematic of a cloud based closed loop control for updating CP unit setpoints of the predetermined thresholds and with use of AI.

The cloud based closed loop controller of FIG. 14 has CP units 6000 on the structure which units are controlled by CP unit controllers 2400 for controlling the corrosion protection according to a setpoint for the structure 5000. The setpoint starts as an ideal setpoint 6350 providing ideal polarisation. However since there is a collection of many inputs then a feedback is provided of whether the setpoints are in range (not exceeding threshold) and are optimized to give best CP effect.

The plurality of test point monitors 2100 act as sensors and collect polarisation measurements at discrete locations and times along the structure 5000. Since these are fast synchronous measurements a set of measured polarisation values are obtained in a short period (of the order of a second).

The As per FIG. 2 the test point monitors 2200 and the CP units 6000 and CP controllers 2400 are associated with the structure 5000. However the processing of the monitored polarisation values at the controlled instant off times can be assessed in the cloud 7000 by cloud processing system.

The cloud processing system includes various receivers of data including the set of polarisation data 6320 from the sensors 2100, and ancillary data 6360 like temperature, soil resistivity, moisture levels etc. to evaluate a control signal with a new limited setpoint 6650 to be sent to the TRU via the TRU controller. A limiter, governor or envelope controller may act on the signal to ensure plant limits are not exceeded.

The governed setpoint signal is sent to the TRU Monitor/controller which sets a setpoint to the TRU. (note TRUs are often controlled power supplies which employ their own local control circuits to ensure their output equals their setpoint, the time factor of this local control circuit is faster than the cloud based control loop so it can be largely disregarded.)

At the highest level, the aim is to ensure that the entirety of the structure 5000 meets polarisation criteria (such as −850 mv to CSE) Also there is a need to not exceed upper limits (over protection) which is pre-defined (such as −2000 mV).

Instant-Off measurements (polarisation values) are measured by Test Point Monitors 2200 and sent to the cloud based control system through various communication channels. The polarisation values 6320 are grouped into a set based on rules that are applied to the CP System Model (13) that has been defined through a user interface.

A Preprosessor (7300) applies Preprocessing logic to this data as well as ancillary variables (6360) which can come from API's or other data sources or from IoT equipment. The pre-processing logic can take any form and be highly complex, which can yield a process value which is based on the logic, and all input data. It can also yield high and low limit values.

The process value which was calculated by is compared by the comparator 7400 with the desired setpoint 6350 which could be supplied through user interface or API or various data sources and models. Outputs from the comparator can be an error signal which is sent to the digital logic controller 7500, where the error signal is further evaluated and modified utilising highly complex logic, and can interface with AI Controllers 6500 and external data 6340 through API's.

Outputs from the digital logic controller 7500 is a new setpoint which is sent to a governor 7600 or limiter which can limit the setpoint based on data from the preprocessor 7300 and user defined limits which were supplied through a user interface. The output from the governor 7600 is a limited setpoint 6650 which is sent to the CP Unit Controller 2400 over wireless communication channels and applied the to the CP Unit 6000 (or Transformer Rectifier Unit) to adjust the controls of the setpoint for the CP Unit based on the multiple feedback.

In an example of an operating example there could be 10 sensors 2100 and 2 TRU's 6000 (equipped with controllers 2400) existing on a structure 5000. The 10 sensors evaluate polarisaiton at 10 discrete locations and this data set 6320 is fed to the controller 7500. The controller 7500 determines that 5 sensors are under the ideal value (in magnitude) and applies a step increase to the set point. This new setpoint is assessed by the governor 7600 as the limiter, which determines if any sensors are exceeding the high limit. If not the increased setpoint S1 6650 is sent to the TRU Controller 2400 and adjusts the TRUs setpoint.

This process is iterative and in the next iteration the 10 sensors evaluate polarisaiton at the 10 discrete locations and this data set is fed to the controller. However this time the controller determines that 3 sensors are under the ideal value (in magnitude) and applies a step S2 increase to the set point. This new setpoint is fed into the limiter, but the limiter determines 1 sensor exceeds the high limit so prevents the increase to S2 and outputs S1 which is sent to the TRU Controller and thereby keeps the setpoint at S1

Variations can apply, which relates polarisation at various locations with the output of certain TRU's. i.e. a location near the TRU will be more affected by the output of the TRU than a location far from the TRU thus a “weighting” or model can be developed for a given CP system.

Various ancillary variables 6360 can be included into the control scheme to increase performance. Control variables could be adjusted by a user. Preferably control variables could be adjusted by a machine learning system or functions adjusted by AI controller 6500. Variation of control system controls could be applied including limits, ramp rates, learning functions.

A set of error values (measured value minus setpoint value) could be entered to the logic controller 7500 or the measured values 6320 could be sent directly to the logic controller. (ie the comparator/s could be integral to the logic controller).

### Benefits

The system of the invention differs from the prior art in several ways including the following ways:

### 1) Automation of Instant Off Surveys.

Instant off surveys are used to capture an instant-off potential which is a way to confirm that sufficient cathodic protection is applied. Prior art used a manual system, utilising a wristwatch and a voltmeter to undertake the measurement before continuing to the other test points. There could be a highspeed measurement system where a trendline was measured using a portable oscilloscope or a high-speed data logger that was temporarily connected to the test point. High speed trends would require further analysis to extract the instant off potential. They also use too much power and memory for long term, battery powered applications”

The system of the invention uses the installation and/or initialisation and/or synchronisation of current interrupters at all sources of CP. Current Interrupters switch the CP on and off at specific times. e.g. On at the start of every minute and then off at 50 s past each minute (this is called an interruption pattern). Then a measurement at all test points is taken simultaneously.

It can be seen that the system of the invention has:
a. All sources of CP being automatically interrupted simultaneously with high precision by battery (or externally) powered hardware which is installed permanently on the sources of CP current (Sacrificial anodes and or TRU's) this is done by the CP unit controller
b. after a small, precise and predetermined delay (eg 50 mS) the instant off measurement being measured at all test locations. by test point monitors. This is repeated multiple times through a survey (such as over a 24-hour period)

### 2) Automation of Depolarisation Surveys.

Depolarisation surveys are used to measure the polarisation of the structure with respect to its surrounding electrolyte, when the CP current is applied. This “depolarisation” measurement is one method for determining if the CP is being applied sufficiently

The system requires the installation and/or initialisation and/or synchronisation of current interrupters at all sources of CP. Current Interrupters need to switch the CP off at all sources at a specific time and leave the current interrupted (off).

In prior art systems interruption needs to be for an extended period such as 24 hours the current interrupters are usually temporarily installed. High speed data loggers could be used to measure (approximately) the instant off measurement and the depolarisation of the protected structure (its fall in potential over 24 hours). The high-speed speed data loggers would be collected, the data downloaded and analysed on a PC, and used to determine if there was more than 100 mV between the instant off measurement and the final potential at the end of the survey.

However, regarding the invention:
a. All sources of CP are automatically interrupted simultaneously with high precision by battery (or externally) powered hardware which is installed permanently on the sources of CP current (Sacrificial anodes and or TRU's) this is done by CP unit controller and/or sacrificial anode controller.
b. test point monitors, installed at test locations, accurately measure the instant off potential, then monitor (at intervals) the depolarisation of the asset over the course of the day.

This system reports one or more of:.
Is the criteria met (is the test point protected)?
when was the depolarisation criteria met?
what was the total depolarisation over the course of a day?

In this way, through edge computing, the assessment is automated and done in the field at each test point. The data to be transmitted is limited and suitable for long life IoT equipment. The high-speed data logging of the prior art would require the throughput of extensive amounts of data which is greater than the capability of long battery life IoT devices. This is why the prior art systems are temporarily deployed and collected after the survey.

### 3) Infrequent Interrupt Routine (IIR)

The goal of the instant off survey is to obtain a one instant off measurement at every test point. Previously this requires the interrupters to be running an instant off pattern (on,off,on,off) for a period long enough for the technician to visit each test point sequentially (sometimes days or weeks)

However, with the invention, IoT eliminates the travel time, and the devices are permanently installed at every test point. This means that instead of running an instant-off pattern for hours, days or weeks, there can be a single controlled simultaneous interruption once for say one second at every source of cathodic protection, and simultaneously a single measurement of an instant off potential at every single test point.

This is an entirely new process that provides the data required from an instant off survey but does it in a way that leverages the capability of IoT rather than just mimicking traditional methods.

The system can achieve an instant off measurement at all test points in just 1 second. Thereby due to the ease at which a single instant-off measurement is obtained, it can be done frequently. This system can be operative year-round (hourly, daily or weekly), which means regular instant off measurements can be taken rather than doing it with say an annual campaign.

### 4) Automation of Stray Current Surveys.

Prior art requires the installation of temporarily installed, high speed data loggers which would log the voltage of the structure for a period (say a day). The logger would be collected, the data downloaded and then collated and reviewed to determine for what period the voltage exceeded certain thresholds. This is too much data to be transmitted by long battery life IoT equipment.

Regarding the invention, high-speed measurements are taken for the same period (say a day) but instead of sending all of the data, it is first evaluated automatically in the field and only the number of counts that exceed each of the predetermined thresholds is transmitted. This is a substantial savings in amount of data transmitted and a substantial improvement in real time assessment.

### 5) Closed Loop Control of CP Setpoints

The capability of the system being able to achieve an instant off measurement at all test points in just 1 second, is key to being able to implement closed loop control. The closed loop control should not be done with On-potentials. For it to be accurate the input data needs to be instant-off potentials. IIR is the key to frequent instant off potentials.

Referring to FIG. 13, the taking of synchronously simultaneous readings at the test point monitors over a short time provides a set of measured polarization values that can be used in light of measured environmental variables such as temperature, soil resistivity and soil hydration. The digital logic controller determines new setpoint and limits or governs the setpoint to a limited setpoint forming the threshold used by the TRU. The current and/or voltage output at every source of cathodic protection can be optimised on an hourly or daily basis.

Therefore, the system of the invention provides:
1. IIR which enables regular measurements of the instant-off potential;
2. regular instant off measurements (not possible with the prior art), which enables closed loop control with a cycle time dependent on the IIR frequency;
3. closed loop control which is capable of updating the CP Unit setpoints (and sacrificial anode setpoints) on say an hourly or daily basis
4. insurance that CP is optimised continually and automatically rather than manually and infrequently

Therefore the system of the invention can automatically control the setpoint of TRU's based on the complete set of data received from the test point monitors.

This is a key differentiator and is a major improvement in our industry. IIR is a key building block to enable this capability. Also, this enables AI/ML processing of the data and control of the feedback, which vastly optimises the control and the overall application of CP.

### Inventive Aims

There are two main types of cathodic protection systems (CP) which can be used on pipelines. This choice of pipelines is selected only as an example because they are prevalent and easy to imagine since they are typically linear.

The first type of cathodic protection systems (CP) is an Impressed Current CP System (ICCP).

ICCP systems utilise power supplies, which are called Transformer Rectifier Units (TRU's). They inject Cathodic Protection (CP) current into the protected structure (such as pipeline). The TRU has the Structure on its galvanic negative side and on its positive side a Ground Bed. This is a series of electrodes that allow for electrical continuity into the soil (or water). It should be noted that the electrodes are NOT “sacrificial Anodes” but they are called Anodes”.

In a typical pipeline example, there might be an Impressed current CP system say every 20 km and a Test Point every 1 km.

A Test point in its simplest form is a terminal above ground, that is connected to the Structure (below ground) by a cable. This give an accessible point that is at the same electrical potential as the protected structure.

The second type of cathodic protection systems (CP) is a Sacrificial (or Galvanic) CP System

The cathodic protection systems (CP) are identical to the ICCP. However, instead of CP Units located at long spacings, there are sacrificial anodes made from reactive metals (like zinc or magnesium) installed at short spacings.

The distances of the CP Units, for example, can be located every 20 km, and with the reactive metals (like zinc or magnesium) at about every km.

The Sacrificial anode is able to drive a protective current through the principals of galvanic series of dissimilar metals. These are usually connected to the structure by a cable which passes through the test point to enable connection, disconnection or measurement of the voltage or the current that the anode is delivering.

Some systems can combine TRUs and Sacrificial anodes in what is called a mixed protection system.

### Protection Criteria

There are two main protection criteria Protection is proved by showing compliance to at least one of these.

Criteria 1—Instant Off Criteria is when a sufficiently negative measurement is shown between the structure and its environment immediately after all sources of CP have been turned off (interrupted).

Criteria 2—Depolarisation Criteria is when a sufficient drop in potential (depolarisation) is shown between the instant off potential (potential just after interruption) and its depolarised state (the potential measured between the structure and its environment at a predetermined delay period such as 24 hours after all sources of

In both cases an instant off measurement is required. A measurement with CP applied is called an On-Potential and this contains an Error called the IR (or IxR) error due to current flowing through the soil.

### Inventive Aspects and Benefits

The most inventive aspects of the system in embodiments of the invention include:
a. the system combining 3 types of IoT devices which coordinate to automate different types of surveys and measurements. The 3 types of devices are:
   i. devices to monitor AND control AND interrupt the output of the TRU
   ii. devices to monitor the potential at the test points
   iii. devices that can interrupt sacrificial anodes AND measure the potential at the test point
b. All of these 3 types of devices are synchronised to real time with mS precision through the use of a GNSS receiver
c. No communication is required between any 2 devices. However perfect coordination is ensured by connection to external clock
d. The system coordinates to automate Instant off Measurements at each test point
e. The system coordinates to automate depolarisation surveys
f. the system can synchronously and thereby simultaneously interrupt an unlimited number of anodes and TRUs
g. The system synchronously coordinates to automate Stray current surveys
h. The system uses edge computing to send the relevant data for Stray current and Depolarisation surveys, rather than sending the raw data (which would exceed the capabilities of our communication systems)
i. The system uses an innovative distributed closed loop control system using data from IoT Devices to control setpoints on other IoT devices using computing power in a Cloud platform. This is the first time such a distributed closed loop control system has been attempted (definitely in this field)
j. CP can be optimised everywhere, all of the time
k. By applying AI to the dataset to, among other things, there is achieved optimised CP of large numbers of independent but collocated systems
l. control of current through Sacrificial anodes can be achieved to a finer level of optimisation of CP. (traditionally they have just been turned on/off.

The interplay between different CP'ed assets, such as trains, trams, and power transmission, is a big problem in most cities. To date there has not been a solution. However using machine learning with the IoT data (and closed loop control) CP can be optimized dynamically and simultaneously on multiple assets.

### Interpretation

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein. For the purposes of the present invention, additional terms are defined below. Furthermore, all definitions, as defined and used herein, should be understood to control over dictionary definitions, definitions in documents incorporated by reference, and/or ordinary meanings of the defined terms unless there is doubt as to the meaning of a particular term, in which case the common dictionary definition and/or common usage of the term will prevail.

The terminology used herein is for the purpose of describing particular embodiments only and is not intended to be limiting of the invention. As used herein, the singular articles “a”, “an” and “the” are intended to include the plural forms as well, unless the context clearly indicates otherwise and thus are used herein to refer to one or to more than one (i.e. to “at least one”) of the grammatical object of the article. By way of example, the phrase “an element” refers to one element or more than one element.

The term “about” is used herein to refer to quantities that vary by as much as 30%, preferably by as much as 20%, and more preferably by as much as 10% to a reference quantity. The use of the word ‘about’ to qualify a number is merely an express indication that the number is not to be construed as a precise value.

Throughout this specification, unless the context requires otherwise, the words “comprise”, “comprises” and “comprising” will be understood to imply the inclusion of a stated step or element or group of steps or elements but not the exclusion of any other step or element or group of steps or elements.

The term “real-time” for example “displaying real-time data,” refers to the display of the data without intentional delay, given the processing limitations of the system and the time required to accurately measure the data.

As used herein, the term “exemplary” is used in the sense of providing examples, as opposed to indicating quality. That is, an “exemplary embodiment” is an embodiment provided as an example, as opposed to necessarily being an embodiment of exemplary quality for example serving as a desirable model or representing the best of its kind.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

### Bus

In the context of this document, the term “bus” and its derivatives, while being described in a preferred embodiment as being a communication bus subsystem for interconnecting various devices using protocols such as I2C, Universal Asynchronous Receiver/Transmitter (UART), Serial Peripheral Interface (SPI) and the like, should be construed broadly herein as any system for communicating data, and could include a system on a chip (SoC) configuration.

In accordance with:

As described herein, ‘in accordance with’ may also mean ‘as a function of’ and is not necessarily limited to the integers specified in relation thereto.

### Composite Items

As described herein, ‘a computer implemented method’ should not necessarily be inferred as being performed by a single computing device such that the steps of the method may be performed by more than one cooperating computing devices.

Similarly objects as used herein such as ‘web server’, ‘server’, ‘client computing device’, ‘computer readable medium’ and the like should not necessarily be construed as being a single object, and may be implemented as a two or more objects in cooperation, such as, for example, a web server being construed as two or more web servers in a server farm cooperating to achieve a desired goal or a computer readable medium being distributed in a composite manner, such as program code being provided on a compact disk activatable by a license key downloadable from a computer network.

### Database:

In the context of this document, the term “database” and its derivatives may be used to describe a single database, a set of databases, a system of databases or the like. The system of databases may comprise a set of databases wherein the set of databases may be stored on a single implementation or span across multiple implementations. The term “database” is also not limited to refer to a certain database format rather may refer to any database format. For example, database formats may include MySQL, MySQLi, XML or the like.

### Wireless:

The invention may be embodied using devices conforming to other network standards and for other applications, including, for example other WLAN standards and other wireless standards. Applications that can be accommodated include IEEE 802.11 wireless LANs and links, and wireless Ethernet.

In the context of this document, the term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. In the context of this document, the term “wired” and its derivatives may be used to describe circuits, devices, systems, methods, techniques, communications channels, etc., that may communicate data through the use of modulated electromagnetic radiation through a solid medium. The term does not imply that the associated devices are coupled by electrically conductive wires.

### Processes:

Unless specifically stated otherwise, as apparent from the following discussions, it is appreciated that throughout the specification discussions utilizing terms such as “processing”, “computing”, “calculating”, “determining”, “analysing” or the like, refer to the action and/or processes of a computer or computing system, or similar electronic computing device, that manipulate and/or transform data represented as physical, such as electronic, quantities into other data similarly represented as physical quantities.

### Processor:

In a similar manner, the term “processor” may refer to any device or portion of a device that processes electronic data, e.g., from registers and/or memory to transform that electronic data into other electronic data that, e.g., may be stored in registers and/or memory. A “computer” or a “computing device” or a “computing machine” or a “computing platform” may include one or more processors.

The methodologies described herein are, in one embodiment, performable by one or more processors that accept computer-readable (also called machine-readable) code containing a set of instructions that when executed by one or more of the processors carry out at least one of the methods described herein. Any processor capable of executing a set of instructions (sequential or otherwise) that specify actions to be taken are included. Thus, one example is a typical processing system that includes one or more processors. The processing system further may include a memory subsystem including main RAM and/or a static RAM, and/or ROM.

### Computer-Readable Medium:

Furthermore, a computer-readable carrier medium may form, or be included in a computer program product. A computer program product can be stored on a computer usable carrier medium, the computer program product comprising a computer readable program means for causing a processor to perform a method as described herein.

### Networked or Multiple Processors:

In alternative embodiments, the one or more processors operate as a standalone device or may be connected, e.g., networked to other processor(s), in a networked deployment, the one or more processors may operate in the capacity of a server or a client machine in server-client network environment, or as a peer machine in a peer-to-peer or distributed network environment. The one or more processors may form a web appliance, a network router, switch or bridge, or any machine capable of executing a set of instructions (sequential or otherwise) that specify actions to be taken by that machine.

Note that while some diagram(s) only show(s) a single processor and a single memory that carries the computer-readable code, those in the art will understand that many of the components described above are included, but not explicitly shown or described in order not to obscure the inventive aspect. For example, while only a single machine is illustrated, the term “machine” shall also be taken to include any collection of machines that individually or jointly execute a set (or multiple sets) of instructions to perform any one or more of the methodologies discussed herein.

### Additional Embodiments:

Thus, one embodiment of each of the methods described herein is in the form of a computer-readable carrier medium carrying a set of instructions, e.g., a computer program that are for execution on one or more processors. Thus, as will be appreciated by those skilled in the art, embodiments of the present invention may be embodied as a method, an apparatus such as a special purpose apparatus, an apparatus such as a data processing system, or a computer-readable carrier medium. The computer-readable carrier medium carries computer readable code including a set of instructions that when executed on one or more processors cause a processor or processors to implement a method. Accordingly, aspects of the present invention may take the form of a method, an entirely hardware embodiment, an entirely software embodiment or an embodiment combining software and hardware aspects. Furthermore, the present invention may take the form of carrier medium (e.g., a computer program product on a computer-readable storage medium) carrying computer-readable program code embodied in the medium.

### Carrier Medium:

The software may further be transmitted or received over a network via a network interface device. While the carrier medium is shown in an example embodiment to be a single medium, the term “carrier medium” should be taken to include a single medium or multiple media (e.g., a centralized or distributed database, and/or associated caches and servers) that store the one or more sets of instructions. The term “carrier medium” shall also be taken to include any medium that is capable of storing, encoding or carrying a set of instructions for execution by one or more of the processors and that cause the one or more processors to perform any one or more of the methodologies of the present invention. A carrier medium may take many forms, including but not limited to, non-volatile media, volatile media, and transmission media.

### Implementation:

It will be understood that the steps of methods discussed are performed in one embodiment by an appropriate processor (or processors) of a processing (i.e., computer) system executing instructions (computer-readable code) stored in storage. It will also be understood that the invention is not limited to any particular implementation or programming technique and that the invention may be implemented using any appropriate techniques for implementing the functionality described herein. The invention is not limited to any particular programming language or operating system.

### Means For Carrying out a Method or Function

Furthermore, some of the embodiments are described herein as a method or combination of elements of a method that can be implemented by a processor of a processor device, computer system, or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

### Connected

Similarly, it is to be noticed that the term connected, when used in the claims, should not be interpreted as being limitative to direct connections only. Thus, the scope of the expression a device A connected to a device B should not be limited to devices or systems wherein an output of device A is directly connected to an input of device B. It means that there exists a path between an output of A and an input of B which may be a path including other devices or means. “Connected” may mean that two or more elements are either in direct physical or electrical contact, or that two or more elements are not in direct contact with each other but yet still co-operate or interact with each other.

### Embodiments:

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the above description of example embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description of Specific Embodiments are hereby expressly incorporated into this Detailed Description of Specific Embodiments, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

### Specific Details

In the description provided herein, numerous specific details are set forth. However, it is understood that embodiments of the invention may be practiced without these specific details. In other instances, well-known methods, structures and techniques have not been shown in detail in order not to obscure an understanding of this description.

It will be appreciated that the methods/apparatus/devices/systems described/illustrated above at least substantially provide a corrosion protection system and test point monitor therefor.

The corrosion protection system described herein, and/or shown in the drawings, are presented by way of example only and are not limiting as to the scope of the invention. Unless otherwise specifically stated, individual aspects and components of the corrosion protection system may be modified, or may have been substituted therefore known equivalents, or as yet unknown substitutes such as may be developed in the future or such as may be found to be acceptable substitutes in the future. The corrosion protection system may also be modified for a variety of applications while remaining within the scope and spirit of the claimed invention, since the range of potential applications is great, and since it is intended that the present invention be adaptable to many such variations.

### Terminology

In describing the preferred embodiment of the invention illustrated in the drawings, specific terminology will be resorted to for the sake of clarity. However, the invention is not intended to be limited to the specific terms so selected, and it is to be understood that each specific term includes all technical equivalents which operate in a similar manner to accomplish a similar technical purpose. Terms such as “forward”, “rearward”, “radially”, “peripherally”, “upwardly”, “downwardly”, and the like are used as words of convenience to provide reference points and are not to be construed as limiting terms.

### Different Instances of Objects

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

### Comprising and Including

In the claims which follow and in the preceding description of the invention, except where the context requires otherwise due to express language or necessary implication, the word “comprise” or variations such as “comprises” or “comprising” are used in an inclusive sense, i.e. to specify the presence of the stated features but not to preclude the presence or addition of further features in various embodiments of the invention.

Any one of the terms: including or which includes or that includes as used herein is also an open term that also means including at least the elements/features that follow the term, but not excluding others. Thus, including is synonymous with and means comprising.

### Scope of Invention

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. For example, any formulas given above are merely representative of procedures that may be used. Functionality may be added or deleted from the block diagrams and operations may be interchanged among functional blocks. Steps may be added or deleted to methods described within the scope of the present invention.

Although the invention has been described with reference to specific examples, it will be appreciated by those skilled in the art that the invention may be embodied in many other forms.

### Chronological Order

For the purpose of this specification, where method steps are described in sequence, the sequence does not necessarily mean that the steps are to be carried out in chronological order in that sequence, unless there is no other logical manner of interpreting the sequence.

### Markush Groups

In addition, where features or aspects of the invention are described in terms of Markush groups, those skilled in the art will recognise that the invention is also thereby described in terms of any individual member or subgroup of members of the Markush group.

### Industrial Applicability

It is apparent from the above, that the arrangements described are applicable to the cathodic protection industries.

1. A corrosion protection system for preventing the corrosion of a structure being protected, the system including:
a. a plurality of monitors wherein each monitor has:
i. a connection configured for connection between a reference cell and the structure for assessing an electrical potential in the structure to form a test point monitor monitoring a single test point, transformer rectifier unit (RFU) or sacrificial anode;
ii. an internal clock;
iii. a processor operatively configured for executing instructions;
iv. at least one or more transceivers configured for receiving and transmitting data and/or time signals;
v. a potential sensor for sensing the potential between the structure and the surrounding environment;
vi. a digital storage media operatively connected to the processor;
wherein each monitor is configured for:
1. receiving a first time signal from a first external clock;
2. synchronizing the internal clock according to the received first time signal from the first external clock;
3. receiving a scheduling signal indicative of the scheduling of a survey event of at least one or more corrosion protection (CP) units located on the structure; and
4. measuring the potential between the structure and the surrounding environment relative to the reference cell at a predetermined time relative to the scheduled survey event.
b. and the system further includes at least one or more corrosion protection (CP) units, wherein at least one or more CP units or sacrificial anodes include:
i. a connection configured for connection between a power source and the structure for providing electrical potential being created in the structure as corrosion protection over a defined period;
ii. an internal clock;
iii. a processor operatively configured for executing digital instructions;
iv. an interrupter configured for interrupting the electrical potential being created in the structure;
v. at least one or more transceivers configured for receiving and transmitting data and/or time signals;
vi. digital storage media operatively connected to the processor
vii. wherein each CP unit is configured for:
1. receiving the first time signal from the first external clock;
2. synchronizing the internal clock according to the received time signal from the first external clock;
3. receiving a scheduling signal indicative of the scheduling of a survey event of at least one or more CP units located on the structure; and
4. interrupting the electrical potential between the structure and the surrounding environment at the scheduled survey event.
c. wherein simultaneous interruption for say one second, allows simultaneous measurement at every single test point at an instant off or low electrical potential.

2. The corrosion protection system as claimed in claim 1, wherein the system is configured for cathodic protection management by
a. Continually monitoring of
i. on-potential of CP units or sacrificial anodes and
ii. instant off;
b. and undertaking one or more regular surveys of:
i. stray current
ii. instant off; and
iii. depolarisation.

3. The corrosion protection system as claimed in claim 2, wherein a regular survey includes
a. high-speed measurements are collected for the same period; and
b. the data is first automatically evaluated; and
c. only the number of counts that exceed each of predetermined thresholds is transmitted.

4. The corrosion protection system as claimed in claim 3, wherein the CP units includes:
a. Sacrificial anodes or
b. Cathodic protection transformer rectifier units (TRU)
and wherein system automatically controls the setpoint of TRU's based on the complete set of data received from the test point monitors and wherein the system synchronously interrupts an unlimited number of anodes and TRUs and coordinates to automate a instant off survey or a depolarization survey at each of the single test points.

5. The corrosion protection system as claimed in claim 1, wherein the test point monitor has a high input impedance of greater than 150 and preferably an input impedance of 200 megaohms.

6. A method of monitoring the corrosion protection of a structure being protected, the method being carried out on a test point monitor located between two adjacent CP units of a corrosion protection system and comprising the steps of:
a. receiving a time signal from a geopositioning satellite;
b. synchronizing the internal clock according to the received time signal;
c. receiving a scheduling signal indicative of the scheduling of at least one survey event of at least one or more CP units located on the structure; and
d. measuring the potential between the structure and the surrounding environment at a precise predetermined time after the at least one scheduled survey event wherein the method includes the step of:
i. transitioning to a low-power usage state between receiving the scheduling signal and a predetermined time before the scheduled survey event.
ii. transitioning from a high-power usage state to a low-power usage state after receiving the time signal from a geopositioning satellite.
iii. transmitting the measured potential to a data management system.
wherein the method includes the step of receiving a synchronisation schedule for receiving a time signal from a geopositioning satellite for the synchronisation of all nodes with an external and ever-present time external source (GNSS) which allows coordination of all parts even without communication between parts including and storing the synchronisation schedule and the method includes the step of transitioning from a low-power usage state to a higher power usage state at a predetermined time before receiving the synchronisation schedule and transitioning from a high-power usage state to a lower power usage state after receiving the synchronisation schedule.

7. A corrosion protection system for preventing the corrosion of a structure being protected, the corrosion protection monitoring system including:
a. at least one or more test point monitors;
b. at least one or more CP unit units configured for connection to a power source and for creating an electrical potential in the structure, wherein the at least one or more CP unit units include:
i. an internal clock;
ii. a processor operatively configured for executing digital instructions;
iii. an interrupter configured for interrupting the electrical potential being created in the structure;
iv. at least one or more transceivers configured for receiving and transmitting data;
v. digital storage media operatively connected to the processor and configured for storing instructions configured for directing the processor to carry out the steps of:
1. receiving a time signal from a geopositioning satellite;
2. synchronizing the internal clock according to the received time signal;
3. receiving a scheduling signal indicative of the scheduling of a survey event of at least one or more CP units located on the structure; and
4. interrupting the electrical potential between the structure and
the surrounding environment at the scheduled survey event.
and wherein the corrosion protection system includes a controller.

8. The corrosion protection system as claimed in claim 7, wherein the instructions may be configured for directing the processor to carry out the step of receiving a feedback signal from a controller for correcting the potential to be applied to the structure.

9. The corrosion protection system as claimed in claim 7, wherein the instructions may be configured for directing the processor to carry out the step of adjusting the potential applied to the structure in accordance with the feedback signal.

10. A method of predicting the effectiveness of cathodic protection of a structure being protected by a cathodic protection system, the method comprising the steps of:
a. training an machine learning model on data of variables selected from one or more of:
i. potential measurements of potential difference between a structure being protected by a cathodic protection system and its environment at the location of multiple monitors and/or CP units disposed on the structure;
ii. the geopositioning of the monitors and/or CP units;
iii. geological structures proximate the locations of the monitors and/or CP units;
iv. current and/or past weather conditions at the locations of the monitors and/or CP units;
v. groundwater data at the locations of the monitors and/or CP units;
b. generating a prediction model from the trained machine learning model;
c. predicting the effect of one or more of the variables on the cathodic protection of the structure.

11. The method as claimed in claim 10, wherein the method includes the step of transmitting a control correction signal to at least one CP unit based on the predicted effect of the variables.

12. The method as claimed in claim 10, wherein the method uses artificial intelligence, preferably in the form of machine learning provided on a server in the controller in order to monitor the data being received from the CP unit and/or test point monitors, in order to predict voltages and/or currents to be applied by the CP units in order to retain the polarisation of the structure within a preferred range. In this way, control of individual CP units are made more accurate in order to account for local effects such as ground moisture, ground composition, proximity to other structures, and the like and further, will allow the system to learn how changing voltages and/or currents applied by one CP unit affects the performance of the corrosion system as it relates to surrounding CP units and/or test point monitors.

13. A CP unit controller for use in the system of claim 1 for controlling a CP unit for preventing the corrosion of a structure being protected, the CP unit controller including:
a. an internal clock;
b. a processor operatively configured for executing digital instructions;
c. at least one or more transceivers configured for receiving and transmitting data;
d. digital storage media operatively connected to the processor and configured for storing instructions configured for directing the processor to carry out the steps of:
i. receiving a time signal from a geopositioning satellite;
ii. synchronizing the internal clock according to the received time signal;
iii. receiving a scheduling signal indicative of the scheduling of a survey event of at least one or more CP units located on the structure;
iv. transmitting an interrupt signal to an interrupter in accordance with the scheduling signal, to thereby interrupt the electrical potential being created in the structure by the CP unit; and
v. measuring the potential between the structure and the surrounding environment at a predetermined time after the scheduled survey event.

14. A corrosion protection control system for preventing the corrosion of a structure being protected, the corrosion protection monitoring system including:
a. a processor operatively configured for executing digital instructions;
b. at least one or more transceivers configured for receiving and transmitting data;
c. digital storage media operatively connected to the processor and configured for storing instructions configured for directing the processor to carry out the steps of:
i. receiving a measured potential signal indicative of the potential between the structure and the surrounding environment at a predetermined time after a scheduled survey event, the potential signal being received from one or more selected from
1. a plurality of CP unit controllers;
2. a plurality of CP units, and
3. a plurality of test point monitors;
ii. determining a feedback signal from the measured potential signals for transmission to each of the one or more selected from:
1. plurality of CP unit controllers; and
2. plurality of CP units; and
iii. transmitting the feedback signal to each of the one or more selected from:
1. a plurality of CP unit controllers; and
2. a plurality of CP units.
wherein the corrosion protection system comprises an internal clock.
and wherein the instructions may be configured for directing the processor to carry out the step of:
transmitting a scheduling signal indicative of the scheduling of a survey event of at least one or more CP units located on the structure to said one or more selected from:
iv. a plurality of CP unit controllers;
v. a plurality of CP units, and
vi. a plurality of test point monitors.

15. The corrosion protection control system as claimed in claim 14, wherein the instructions may be configured for directing the processor to carry out the step of:
determining the feedback signal utilising one or more selected from
i. the geopositioning of the test point monitors and/or CP units;
ii. geological structures proximate the locations of the monitors and/or CP units;
iii. current and/or past weather conditions at the locations of the test point monitors and/or CP units;
iv. atmospheric conditions at the locations of the test point monitors and/or CP units;
v. groundwater data at the locations of the test point monitors and/or CP units.

16. The corrosion protection control system as claimed in claim 14, wherein the instructions may be configured for directing the processor to carry out the step of:
assigning a weighted value to the potential measured at each of the measuring units based on one or more selected from:
i. their proximity to an input unit;
ii. the ambient temperature at the measuring unit;
iii. soil resistivity at the measuring unit;
iv. moisture levels at the measuring unit;
v. atmospheric conditions at the measuring unit; and
vi. the proximity of geological structures.

17. The corrosion protection control system as claimed in claim 14, wherein the instructions may be configured for directing the processor to carry out the step of averaging the measured potential values of a predetermined number of measuring units to either side of an input unit.

18. The corrosion protection control system as claimed in claim 14, wherein the instructions may be configured for directing the processor to carry out the step of dividing the measured potential of the measuring units by the desired potential to get a proportion.

19. The corrosion protection control system as claimed in claim 14, wherein the instructions may be configured for directing the processor to carry out the step of averaging the proportions of a predetermined number of measuring units to either side of an input unit to obtain an averaged proportion for the associated input unit.

20. The corrosion protection control system as claimed in claim 14, wherein the instructions may be configured for directing the processor to carry out the step of generating an adjusted setpoint for the associated input unit in accordance with the averaged proportion.

21. The corrosion protection control system as claimed in claim 14, wherein the instructions may be configured for directing the processor to carry out the step of transmitting the adjusted setpoint to the associated input unit for adjustment of its setpoint as part of the feedback signal.

22. The corrosion protection control system as claimed in claim 14, wherein the instructions may be configured for directing the processor to carry out the step of reducing the setpoint of an input unit if the measured polarisation exceeds a threshold value.

23. A method of controlling a corrosion protection control system for preventing the corrosion of a structure being protected, the method comprising the steps of:
a. receiving a measured potential signal indicative of the potential between the structure and the surrounding environment at a predetermined time after a scheduled survey event, the potential signal being received from one or more selected from
i. a plurality of CP unit controllers;
ii. a plurality of CP units, and
iii. a plurality of test point monitors;
b. determining a feedback signal from the measured potential signals for transmission to each of the one or more selected from:
i. plurality of CP unit controllers; and
ii. plurality of CP units; and
c. transmitting the feedback signal to each of the one or more selected from:
i. a plurality of CP unit controllers; and
ii. a plurality of CP units.
wherein the method includes the step of transmitting a scheduling signal indicative of the scheduling of a survey event of at least one or more CP units located on the structure to said one or more selected from:
iii. a plurality of CP unit controllers;
iv. a plurality of CP units, and
v. a plurality of test point monitors.
and wherein the method includes the step of determining the feedback signal utilising one or more selected from
vi. the geopositioning of the test point monitors and/or CP units;
vii. geological structures proximate the locations of the monitors and/or CP units;
viii. current and/or past weather conditions at the locations of the test point monitors and/or CP units;
ix. atmospheric conditions at the locations of the test point monitors and/or CP units;
x. groundwater data at the locations of the test point monitors and/or CP units.

24. The method of claim 23, wherein the method includes the step of:
assigning a weighted value to the potential measured at each of the measuring units based on one or more selected from:
i. their proximity to an input unit;
ii. the ambient temperature at the measuring unit;
iii. soil resistivity at the measuring unit;
iv. moisture levels at the measuring unit;
v. atmospheric conditions at the measuring unit; and
vi. the proximity of geological structures.

25. The method of claim 23, wherein the method includes the step of averaging the measured potential values of a predetermined number of measuring units to either side of an input unit.

26. The method of claim 23, wherein the method includes the step of dividing the measured potential of the measuring units by the desired potential to get a proportion.

27. The method of claim 23, wherein the method includes the step of averaging the proportions of a predetermined number of measuring units to either side of an input unit to obtain an averaged proportion for the associated input unit.

28. The method of claim 23, wherein the method includes the step of generating an adjusted setpoint for the associated input unit in accordance with the averaged proportion.

29. The method of claim 23, wherein the method includes the step of transmitting the adjusted setpoint to the associated input unit for adjustment of its setpoint as part of the feedback signal.

30. The method of claim 23, wherein the method includes the step of reducing the setpoint of an input unit if the measured polarisation exceeds a threshold value.
